(19) United States
(12) Patent Application Publication
(10) Pub. No.: US 2025/0054873 A1
(43) Pub. Date: Feb. 13, 2025

(54) SEMICONDUCTOR DEVICE INCLUDING AN ALIGNMENT MARK AND METHODS OF FORMATION

(71) Applicant: Taiwan Semiconductor Manufacturing Company, Ltd., Hsinchu (TW)

(72) Inventors: Sung-Hsin YANG, Tainan (TW); Chuan-Cheng TSOU, Tainan City (TW); Chen-Chieh CHIANG, Kaohsiung City (TW)

(21) Appl. No.: 18/446,299

(22) Filed: Aug. 8, 2023

(51) Int. Cl. H01L 23/544; H01L 21/027

(52) U.S. Cl. CPC H01L 23/544; H01L 21/0274; G03F 9/7076; H01L 2223/54426

(57) ABSTRACT

Implementations described herein provide various implementations of gate based alignment patterns for semiconductor process alignment of a substrate on which semiconductor devices are manufactured. In some implementations described herein, a gate based alignment pattern may be included in an alignment mark region in a semiconductor device that is manufactured on the substrate. The alignment mark region may include a plurality of gate structures that are etched to form gate based alignment pattern. The use of the gate based alignment pattern may reduce the likelihood of and/or may prevent the gate based alignment pattern from becoming obscured or covered by residual material byproducts from one or more semiconductor processing operations that are performed to form various layers and/or structures of the semiconductor device.

### BACKGROUND

Fin-based transistors, such as fin field effect transistors (finFETs) and nanostructure transistors (e.g., nanowire transistors, nanosheet transistors, gate-all-around (GAA) transistors, multi-bridge channel transistors, nanoribbon transistors), are three-dimensional structures that include a channel region in a fin (or a portion thereof) that extends above a semiconductor substrate as a three-dimensional structure. A gate structure, configured to control a flow of charge carriers within the channel region, wraps around the fin of semiconductor material. As an example, in a finFET, the gate structure wraps around three sides of the fin (and thus the channel region), thereby enabling increased control over the channel region (and therefore switching of the finFET). As another example, in a nanostructure transistor, the gate structure wraps around a plurality of channel regions in a fin structure such that the gate structure surrounds each of the plurality of channel regions. Source/drain regions (e.g., epitaxial regions) are located on opposing sides of the gate structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A and 2B are diagrams of example regions of a semiconductor device described herein.

FIGS. 3A-3C are diagrams of an example implementation of an alignment mark (or portion thereof) that may be included in a semiconductor device described herein.

FIGS. 4A-4D are diagrams of an example implementation described herein.

FIGS. 5A-5F are diagrams of an example implementation described herein.

FIGS. 6A-6G are diagrams of an example implementation described herein.

FIGS. 7A-7D are diagrams of example implementations of active gate structures and non-active gate structures described herein.

FIGS. 8A-8C are diagrams of example regions of a semiconductor device described herein.

FIGS. 9A-9C are diagrams of example regions of a semiconductor device described herein.

FIGS. 10A and 10B are diagrams of example regions of a semiconductor device described herein.

FIG. 11 is a diagram of an example lithography system described herein.

FIG. 12 is a diagram of an example implementation of performing alignment of a substrate described herein.

FIG. 13 is a diagram of example components of a device associated with semiconductor device including an alignment mark.

FIG. 14 is a flowchart of an example process associated with forming a semiconductor device including an alignment mark described herein.

FIG. 15 is a flowchart of an example process associated with alignment of a semiconductor device using an alignment mark described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Semiconductor devices are manufactured using patterning techniques to transfer layer designs on a photomask or reticle to a semiconductor substrate. The semiconductor devices are built up layer by layer using a sequence of deposition, patterning, and etching techniques, among other examples. Accordingly, the precise alignment of layers in a semiconductor device (referred to as overlay or OVL) is an important parameter of achieving high yield and low rework rate in semiconductor manufacturing.

A substrate may include one or more alignment marks to facilitate precise and repeatable alignment of the substrate across a plurality of semiconductor processing operations. An alignment mark includes a region of the substrate that includes an alignment pattern that can be scanned and tracked to fine-tune the orientation of the substrate. A laser illumination system of a lithography tool, for example, may scan the pattern of the alignment mark to generate alignment data that may be used to determine whether the alignment of the substrate is a pass or a fail. Moreover, the alignment data may be used to generate OVL compensation values for fine-tuning the alignment for subsequent semiconductor processes.

In some cases, the pattern of an alignment mark may become obscured such that the laser illumination system of the lithography tool can no longer reliably scan the pattern. This can occur, for example, where one or more semiconductor process operations result in residual material being retained over the pattern in the alignment mark. In some cases, residual material may be retained over the pattern in the alignment mark because of dishing that occurs when planarizing a dielectric layer over the pattern. The dielectric layer may be planarized in a planarization operation in preparation for performing a subsequent process, such as a replacement gate process in which dummy gate structures of semiconductor devices on the substrate are removed and replaced with metal gate structures. The dishing may result in a height of the top surface of the dielectric layer being lesser near a center of the alignment mark and greater near a perimeter of the alignment mark.

The dishing in the dielectric layer over the pattern in the alignment mark may result in residual metal material from the replacement gate process being retained over the pattern, thereby obscuring the pattern and preventing the laser based illumination system from scanning the pattern. This can result in alignment errors for the substrate, which can degrade the OVL performance for the semiconductor devices on the substrate. The degraded OVL performance may lead to reduced semiconductor device yield, increased alignment times (and, therefore, decreased lithography tool productivity and throughput), and/or increased semiconductor device rework, among other examples.

In some cases, the dishing can be lessened by stopping the planarization of the dielectric layer early, but this can result in insufficient planarization of the dielectric layer. In particular, not enough of the dielectric layer may be removed from on top of the dummy gate structures if the planarization operation is stopped early, which may result in the dummy gate structures being inaccessible through the dielectric layer for the replacement gate process.

Implementations described herein provide various implementations of gate based alignment patterns for semiconductor process alignment of a substrate on which semiconductor devices are manufactured. In some implementations described herein, a gate based alignment pattern may be included in an alignment mark region in a semiconductor device that is manufactured on the substrate. The alignment mark region may include a plurality of gate structures (e.g., dummy gate structures, polysilicon gate structures, metal gate structures) that are etched to form a gate based alignment pattern. The use of the gate based alignment pattern may reduce the likelihood of and/or may prevent the gate based alignment pattern from becoming obscured or covered by residual material byproducts from one or more semiconductor processing operations that are performed to form various layers and/or structures of the semiconductor device. For example, the gate based alignment pattern may enable a gate spacing parameter or design rule for the semiconductor device to be satisfied in the alignment mark region. This may reduce the likelihood of dishing in the dielectric layer above the gate structures in the alignment mark region. The dishing may be prevented (or the magnitude of dishing may be minimized) in that the close spacing of gate structures in the alignment mark region may prevent or reduce the magnitude of polishing pad deformation when the dielectric layer is planarized (e.g., as part of the replacement gate process). The reduced magnitude or prevention of the dishing in the dielectric layer may reduce the likelihood of and/or prevent residual metal material and/or other material, that is deposited as part of the replacement gate process to form the metal gate structures of the semiconductor device, from being retained above the dielectric layer in the alignment mark region. Accordingly, the gate based alignment pattern of the alignment mark region may reduce the likelihood of and/or prevent residual metal material and/or other material from obscuring or blocking the pattern in the alignment mark region.

In this way, the gate based alignment patterns described herein may increase the scanning accuracy and reliability of the laser based illumination system for scanning the gate based alignment patterns. This may reduce the likelihood of alignment errors for the substrate, which may increase the OVL performance for the semiconductor devices on the substrate. The increased OVL performance may enable increased semiconductor device yield to be achieved, may enable reduced alignment times (and, therefore, increased lithography tool productivity and throughput) to be achieved, and/or may result in reduced semiconductor device rework, among other examples. Moreover, the gate based alignment patterns described herein enable reduced dishing for the dielectric layer to be achieved without increasing the likelihood of residual material from the dielectric layer being retained over the dummy gate structures of the semiconductor.

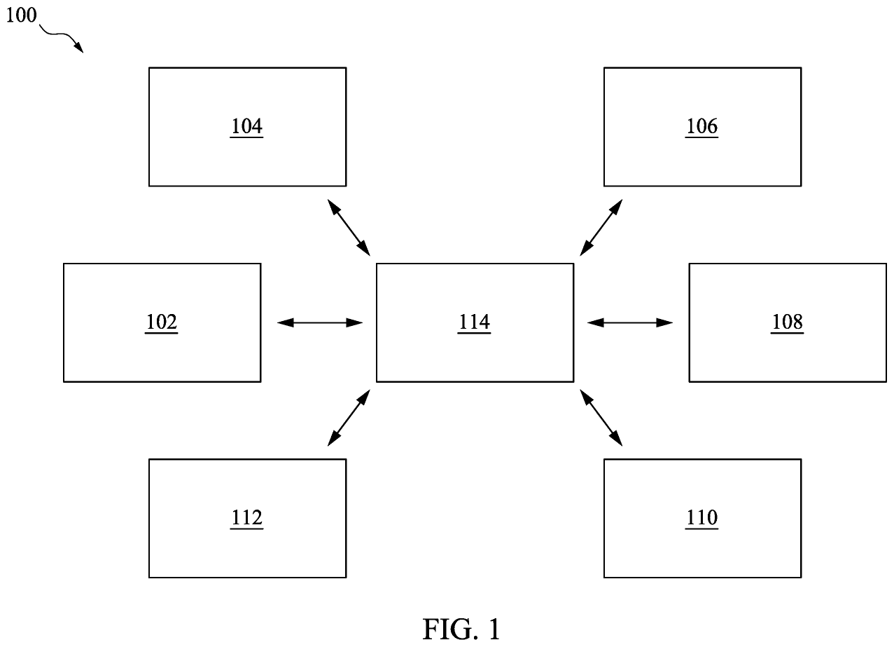

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of deposition tools 102 and/or a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool. In some implementations, the example environment 100 includes a plurality of exposure tools 104 and/or a plurality of types of exposure tools 104.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer. In some implementations, the example environment 100 includes a plurality of developer tools 106 and/or a plurality of types of developer tools 106.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions. In some implementations, the example environment 100 includes a plurality of etch tool 108 and/or a plurality of types of etch tools 108.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar. In some implementations, the example environment 100 includes a plurality of planarization tools 110 and/or a plurality of types of planarization tools 110.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials. In some implementations, the example environment 100 includes a plurality of plating tools 112 and/or a plurality of types of plating tools 112.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114 and/or a plurality of types of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

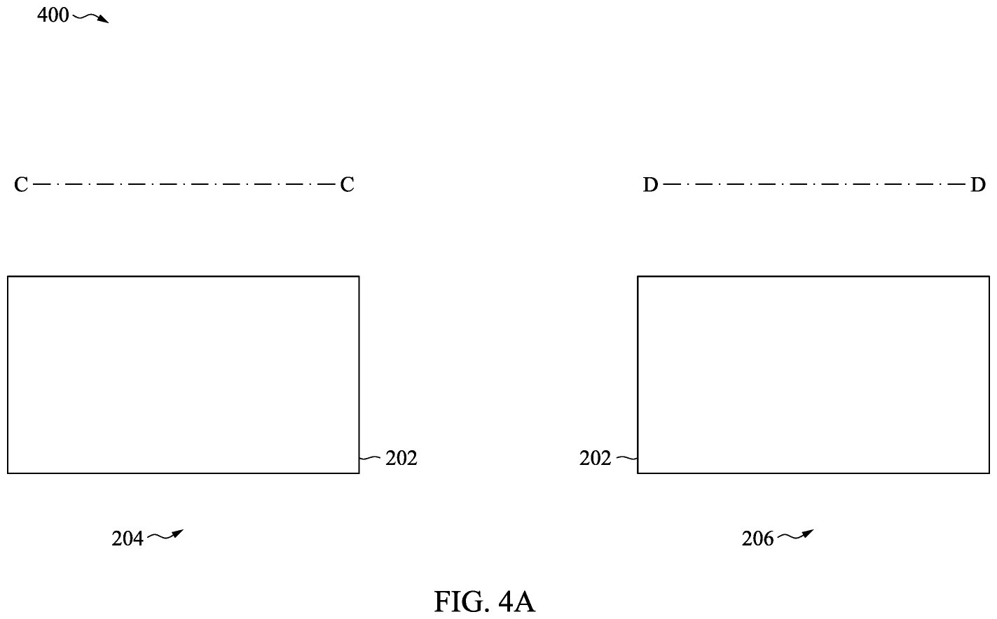

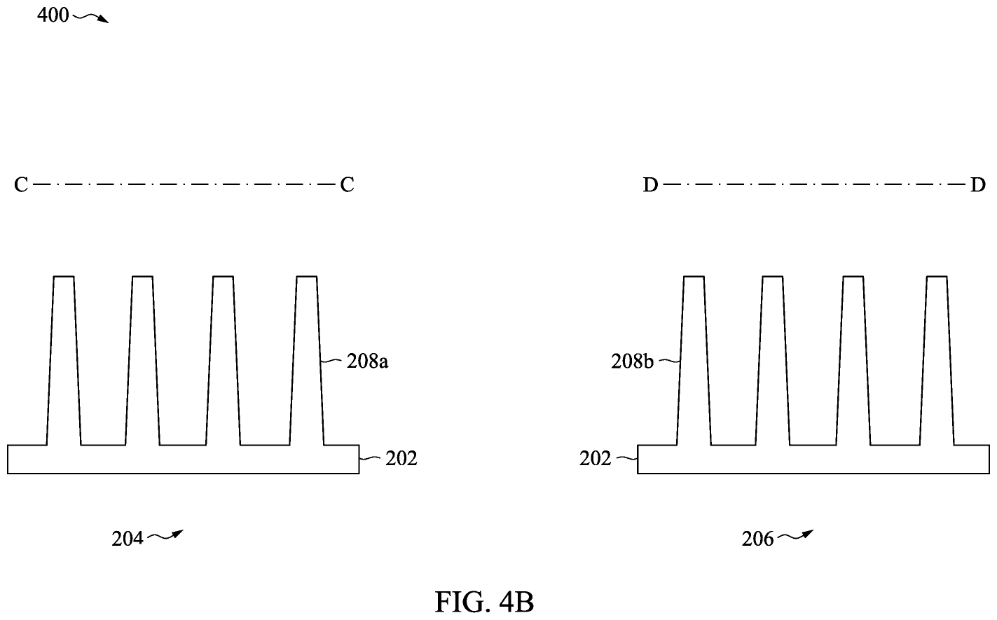

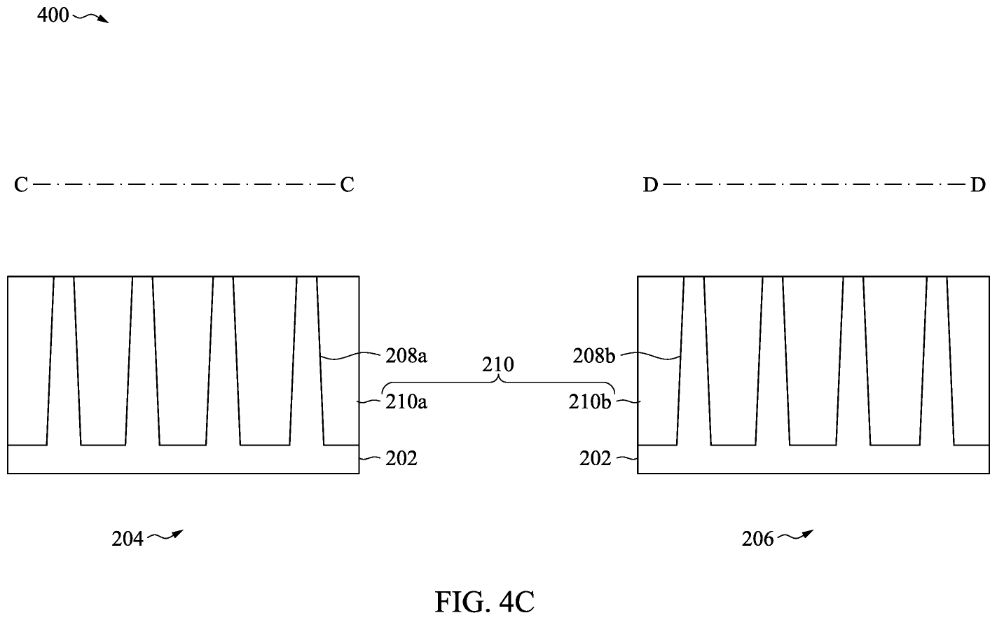

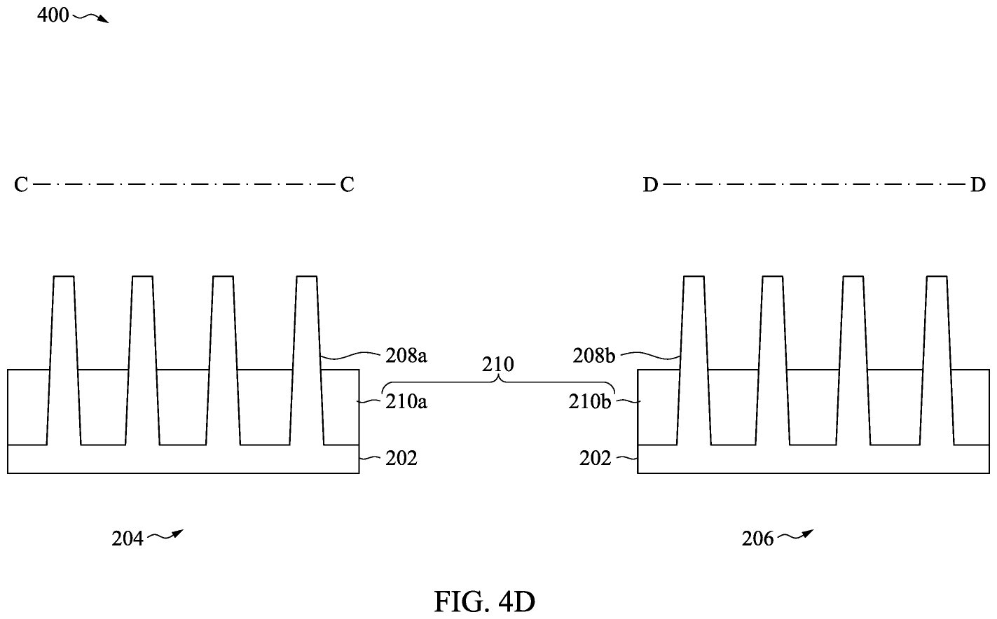

In some implementations, one or more of the semiconductor processing tools 102-114 may perform one or more semiconductor processing operations described herein. For example, one or more of the semiconductor processing tools 102-114 may perform other semiconductor processing operations described herein, such as in connection with FIGS. 4A-4D, 5A-5F, 6A-6G, 11, 12, 14, and/or 15, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

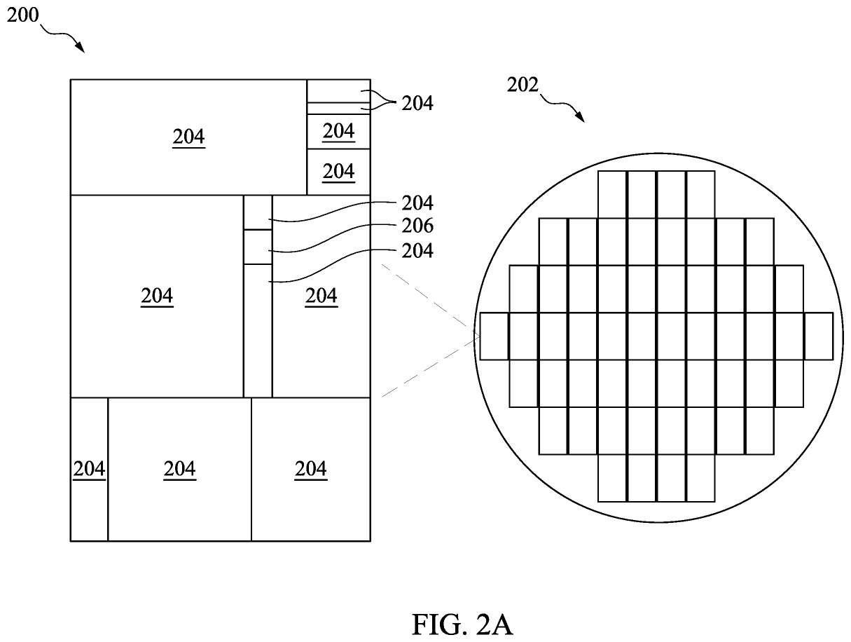

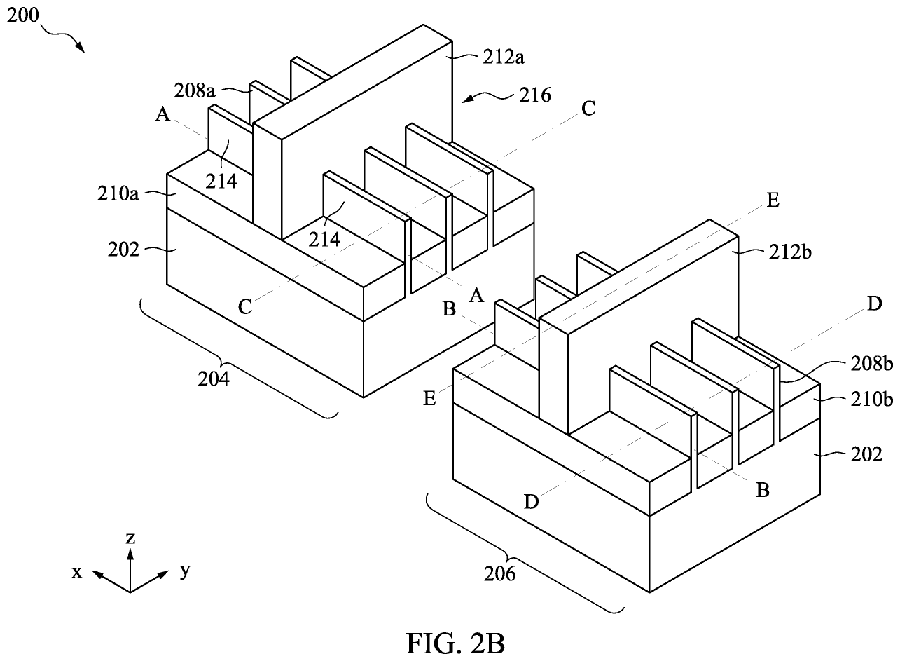

FIGS. 2A and 2B are diagrams of example regions of a semiconductor device 200 described herein. The semiconductor device 200 may include a semiconductor die, a semiconductor chiplet, and/or another type of semiconductor device that is manufactured on a substrate 202.

The substrate 202 includes a silicon (Si) substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, or another type of semiconductor substrate. The substrate 202 may include a round/circular substrate having an approximately 200 mm diameter, an approximately 300 mm diameter, or another diameter, such as 450 mm, among other examples. The substrate 202 may alternatively be any polygonal, square, rectangular, curved, or otherwise non-circular workpiece, such as a polygonal substrate.

The semiconductor device 200 may include one or more active device regions 204 and one or more alignment mark regions 206. The layout, shape, quantity, and/or arrangement of active device regions 204 and alignment mark regions 206 illustrated in FIG. 2A are examples, and other layouts, shapes, quantities, and/or arrangements are within the scope of the present disclosure.

“Active device region 204” refers to a region of the semiconductor device 200 that is functional in the semiconductor device 200's final form. For example, an active device region 204 may include a processor core, another active device region 204 may include a memory region, another active device region 204 may include input/output (I/O), and/or another active device region 204 may include a power management region, among other examples.

“Alignment mark region 206” refers to a region of the semiconductor device 200 that includes a pattern that is used for aligning the substrate 202 in a particular orientation for a semiconductor processing operation such as a lithography or photomasking operation. The alignment mark region 206 may be a region of the semiconductor device 200 that is non-functional in the semiconductor device 200's final form. In some implementations, a plurality of semiconductor devices 200 each include a respective alignment mark region 206 to enable multiple-point alignment to be performed for the substrate 202.

FIG. 2B illustrates perspective views of a portion of an active device region 204 and a portion of an alignment mark region 206. FIGS. 4A-6G are schematic cross-sectional views of various portions of the active device region 204 and the alignment mark region 206 illustrated in FIG. 2B, and correspond to various processing stages of forming fin-based transistors in the active device region 204 and forming a pattern in the alignment mark region 206.

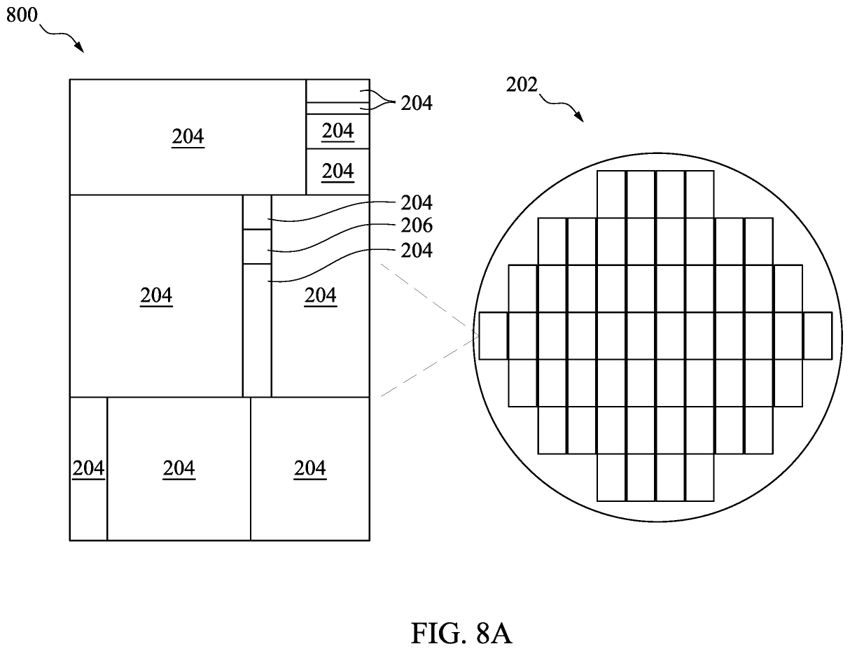

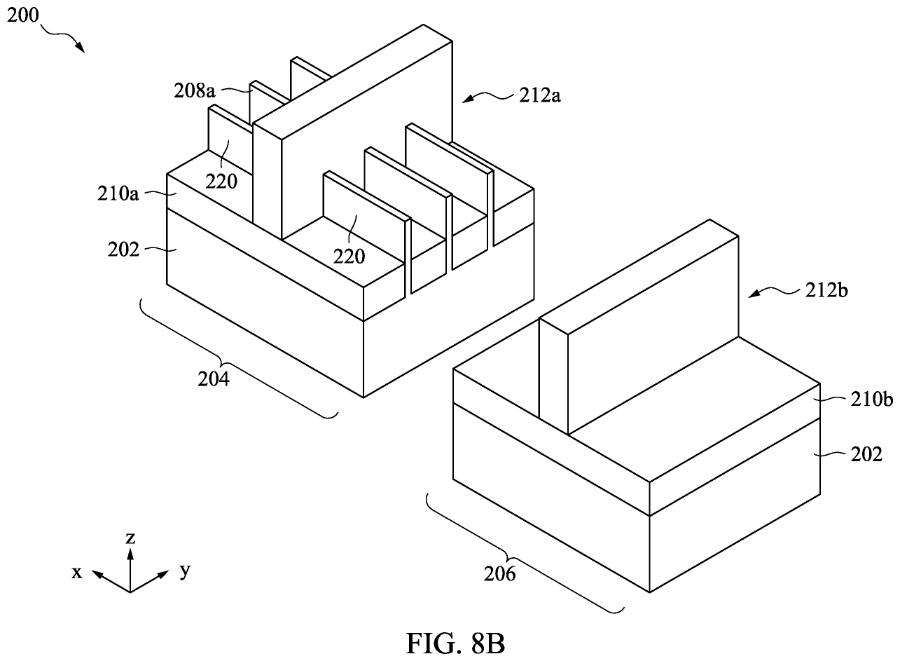

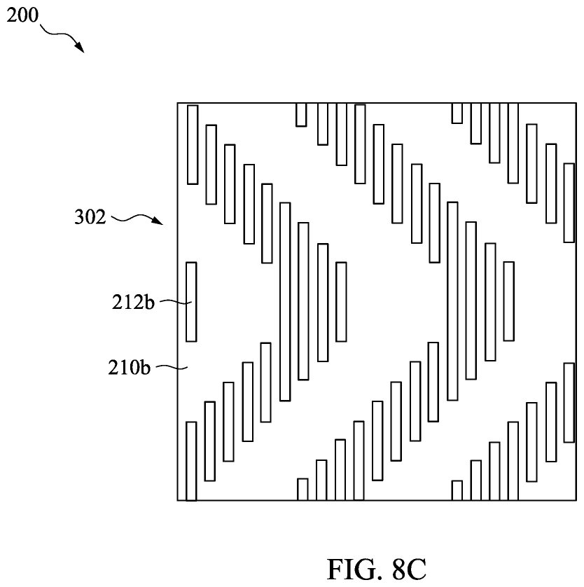

As shown in FIG. 2B, fin structures may be included above the substrate 202 for the active device region 204 and, in some cases, the alignment mark region 206. In particular, fin structures 208a may be included above substrate 202 in the active device region 204. In some implementations, fin structures 208b are included above the substrate 202 in the alignment mark region 206. However, as illustrated in FIGS. 8A and 8B for example, the fin structures 208b may be omitted from the alignment mark region 206.

The fin structures 208a may be referred to as active fin structures in that the fin structures 208a provide an active region where one or more devices (e.g., fin-based transistors) are formed. The fin structures 208b may be referred to as non-active fin structures (or dummy fin structures) in that the fin structures 208b might not be used for the active devices of the semiconductor device 200. In some implementations, the fin structures 208a and 208b include silicon materials or another elementary semiconductor material, such as germanium, or a compound semiconductor material such as silicon carbide, gallium arsenic, gallium phosphide, indium phosphide, indium arsenide, and/or indium antimonide. In some implementations, the fin structures 208a and 208b may include an alloy semiconductor material such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or a combination thereof. In some implementations, the fin structures 208a and 208b may be doped using n-type and/or p-type dopants.

The fin structures 208a and 208b are fabricated by suitable semiconductor process techniques, such as masking, photolithography, and/or etch processes, among other examples. As an example, the fin structures 208a and 208b may be formed by etching a portion of the substrate 202 away to form recesses in the substrate 202. The recesses may then be filled with isolating material that is recessed or etched back to form shallow trench isolation (STI) regions 210a above the substrate 202 and between the fin structures 208a, and STI regions 210b above the substrate 202 and between the fin structures 208b. Other fabrication techniques for the STI regions 210a and 210b and/or the fin structures 208a and 208b may be used. The STI regions 210a and 210b may electrically isolate adjacent active areas in the fin structures 208a and 208b and/or may provide structural support for the fin structures 208a and 208b. The STI regions 210a and 210b may include a dielectric material such as a silicon oxide (SiOₓ), a silicon nitride (SiₓN_{y}), a silicon oxynitride (SiON), fluoride-doped silicate glass (FSG), a low-k dielectric material, and/or other suitable insulating material. The STI regions 210a and 210b may include a multi-layer structure, for example, having one or more liner layers.

A plurality of dummy gate structures 212a are included in the active device region 204 over the fin structures 208a (e.g., approximately perpendicular to the fin structures 208a). A plurality of dummy gate structures 212b are included in the alignment mark region 206 over the fin structures 208b (e.g., approximately perpendicular to the fin structures 208b). The dummy gate structures 212a and/or the dummy gate structures 212b may each include polysilicon (poly or PO) structures, and may therefore be referred to as dummy poly structures. Additionally and/or alternatively, the dummy gate structures 212a and/or the dummy gate structures 212b may each include one or more layers, such as a gate dielectric layer, a gate electrode layer, and/or a hard mask layer, among other examples. A dummy gate structure 212a may include portions that wrap around at least three sides of one or more fin structures 208a and portions that are on top of the STI regions 210a. A dummy gate structure 212b may include portions that wrap around at least three sides of one or more fin structures 208b and portions that are on top of the STI regions 210b.

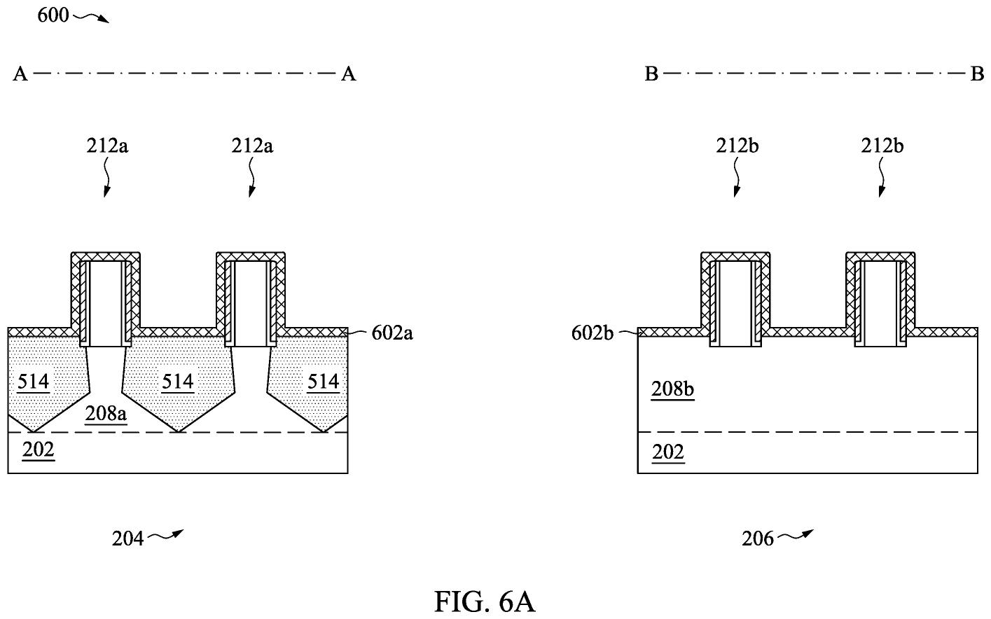

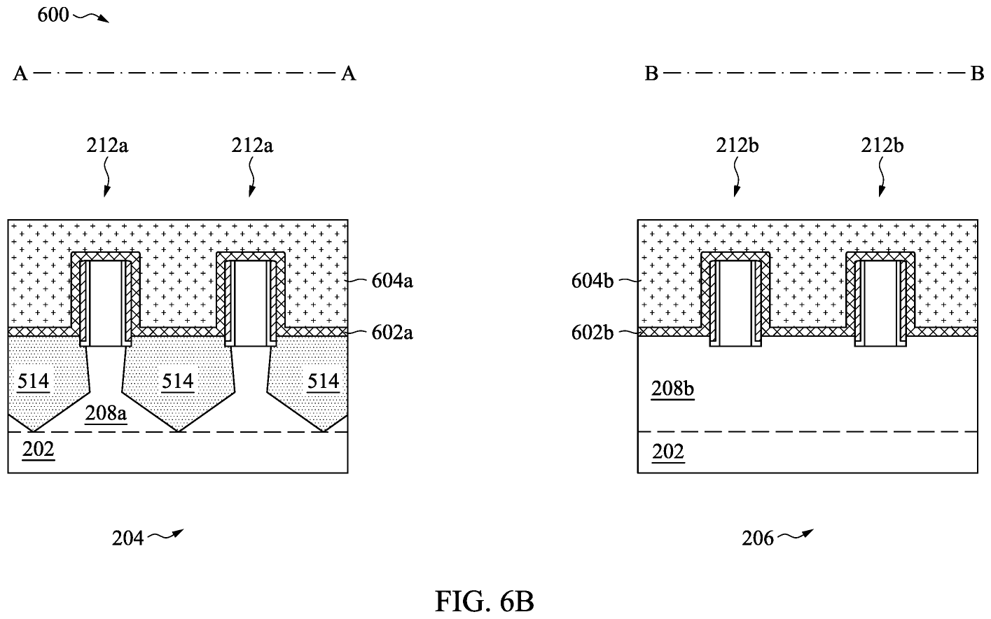

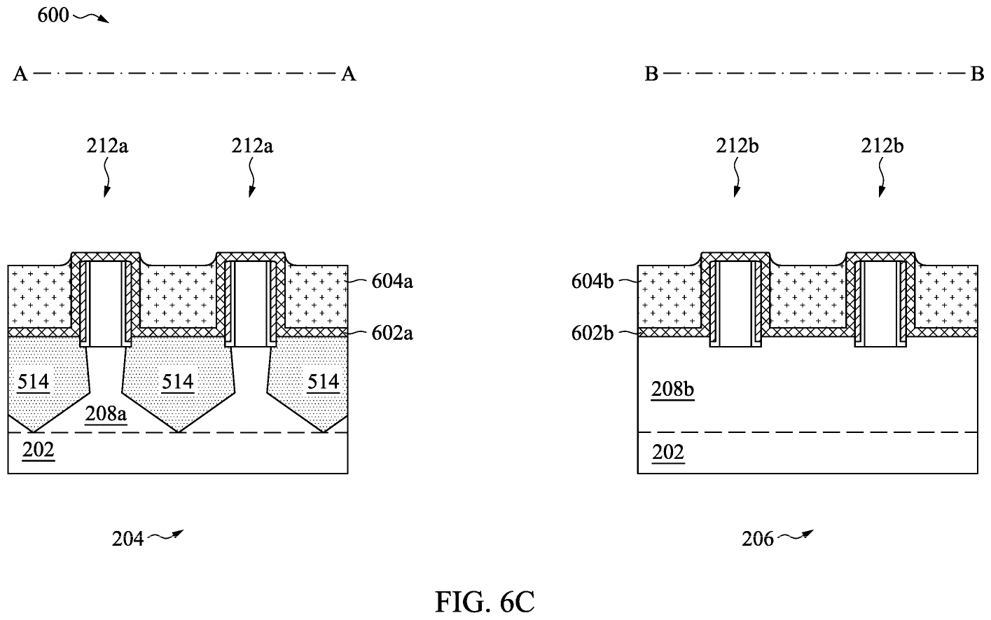

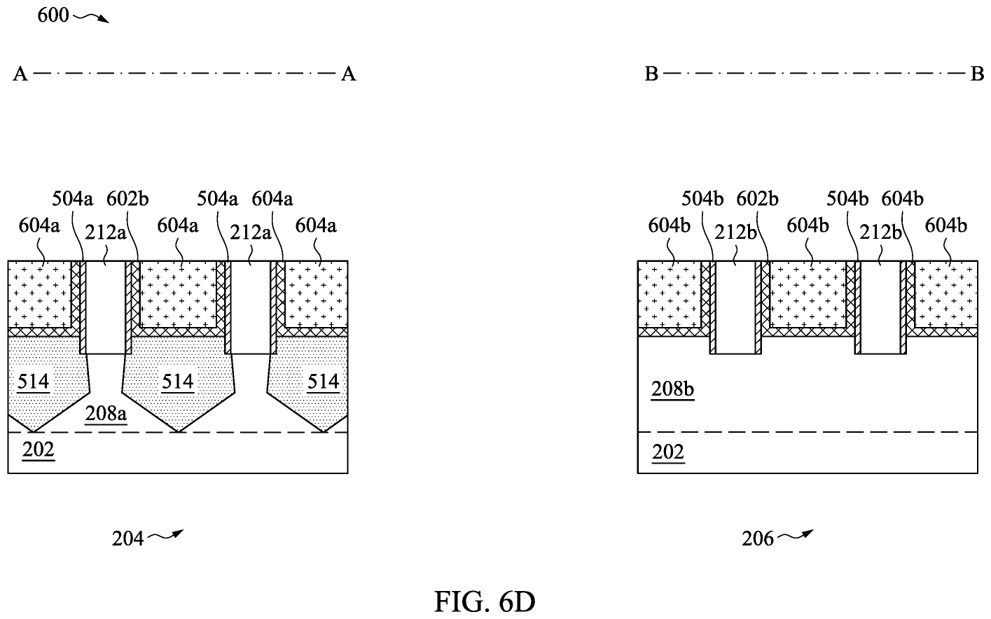

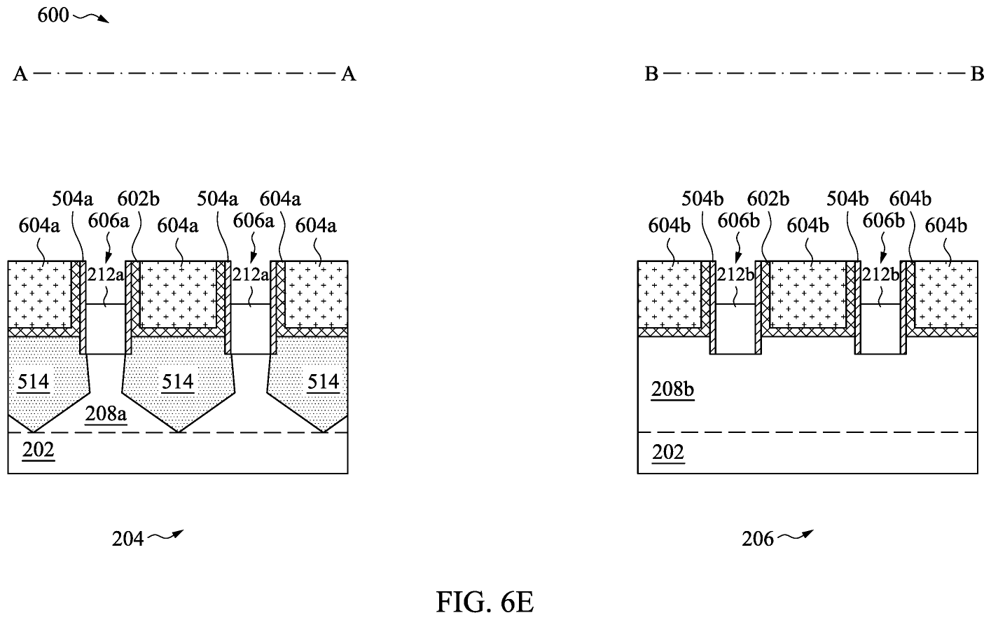

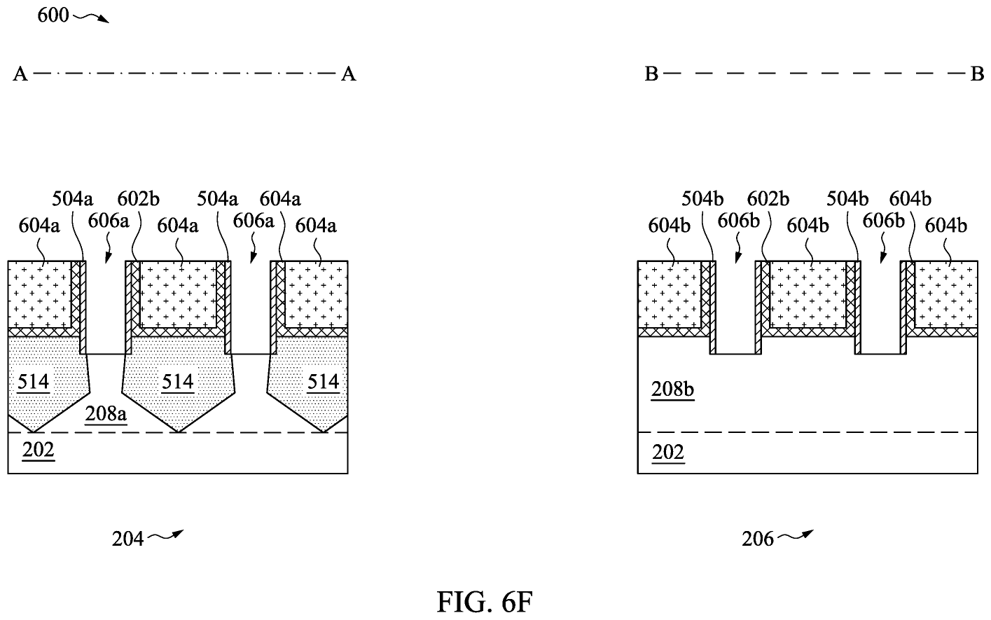

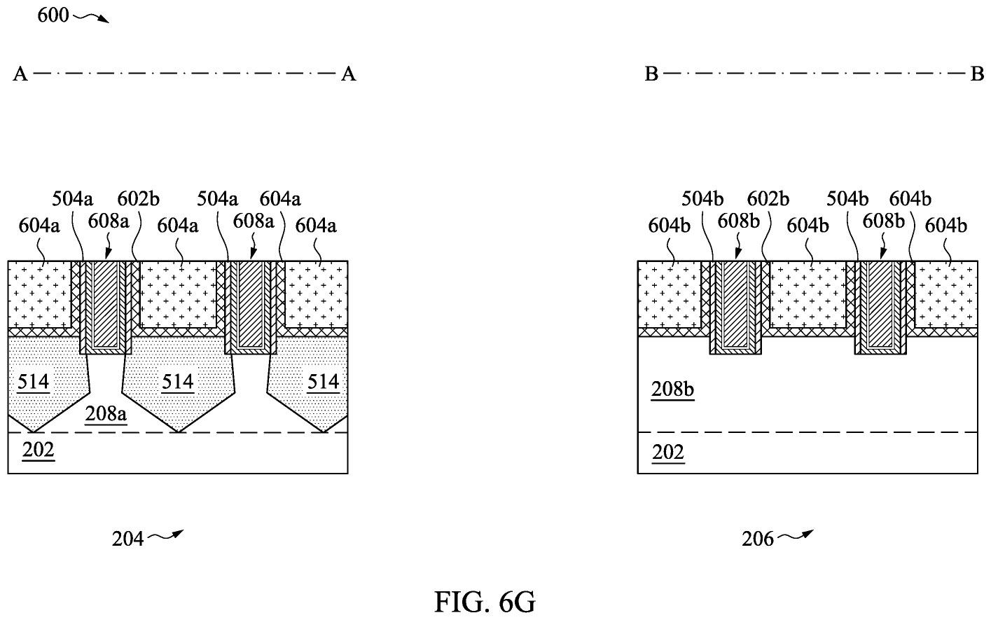

The term “dummy”, as used herein, refers to a sacrificial structure which will be removed in a later stage and will be replaced with another structure, such as a metal gate structure that includes high dielectric constant (high-k) dielectrics and/or metal layers. The process for replacing the dummy gate structures 212a and 212b with metal gate structures may be referred to as a replacement gate process (RGP), an example process of which is illustrated and described in connection with FIGS. 6A-6G.

Source/drain areas 214 are disposed in opposing regions of the fin structures 208a with respect to the dummy gate structure 212a. “Source/drain” may refer to a source or a drain, individually or collectively, dependent upon the context. The source/drain areas 214 include areas in the active device region 204 in which source/drain regions of active transistor structures 216 are formed in the active device region 204. The source/drain regions in the active device region 204 may include silicon (Si) that is epitaxially grown on the fin structures 208a. In some implementations, the source/drain regions may be doped with one or more types of dopants, such as a p-type material and/or an n-type material. A p-type material may include boron (B) or germanium (Ge), among other examples. An n-type material may include phosphorous (P) or arsenic (As), among other examples.

Some source/drain regions may be shared between various transistors in the active device region 204. In some implementations, various ones of the source/drain regions may be connected or coupled together such that fin-based transistors in the active device region 204 are implemented as two functional transistors. For example, if neighboring (e.g., as opposed to opposing) source/drain regions are electrically connected, such as through coalescing the regions by epitaxial growth (e.g., neighboring source/drain regions, as opposed to source/drain regions on opposing sides of a dummy gate structure 212a, being coalesced), two functional transistors may be implemented. Other configurations in other examples may implement other numbers of functional transistors.

FIG. 2B further illustrates reference cross-sections that are used in later figures, including FIGS. 4A-6G among other examples. Cross-section A-A is in a plane along a channel in a fin structure 208a between opposing source/drain areas 214. Cross-section B-B is in a plane along a channel in a fin structure 208b. Cross-section C-C is in a plane perpendicular to cross-section A-A, and is across a source/drain area 214 in fin structure 208a. Cross-section D-D is in a plane perpendicular to cross-section B-B and is across a plurality of fin structures 208b and STI regions 210b. Cross-section E-E is also in a plane perpendicular to cross-section B-B and is along a dummy gate structure 212b in the alignment mark region 206. Subsequent figures refer to these reference cross-sections for clarity. In some figures, some reference numbers of components or features illustrated therein may be omitted to avoid obscuring other components or features for ease of depicting the figures.

As indicated above, FIGS. 2A and 2B are provided as an example. Other examples may differ from what is described with regard to FIGS. 2A and 2B.

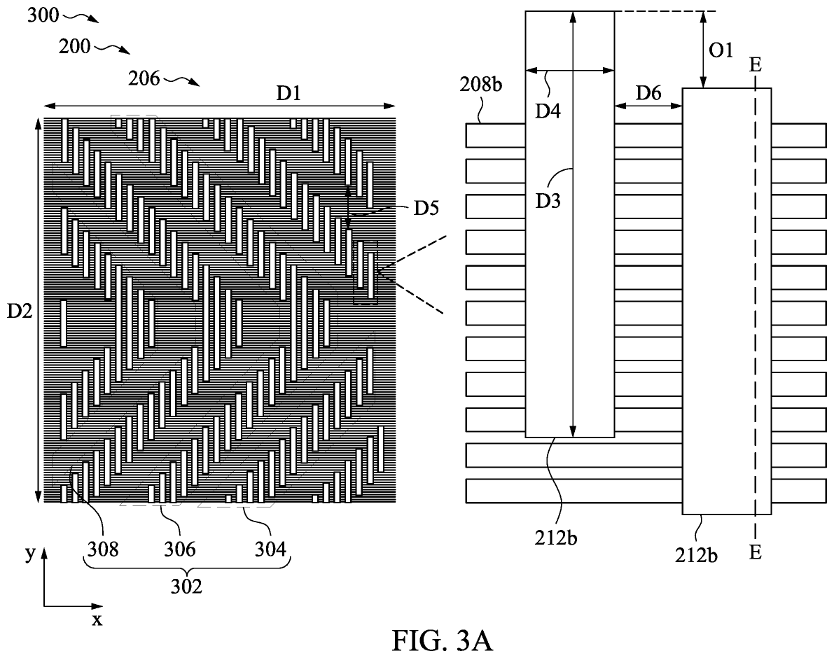

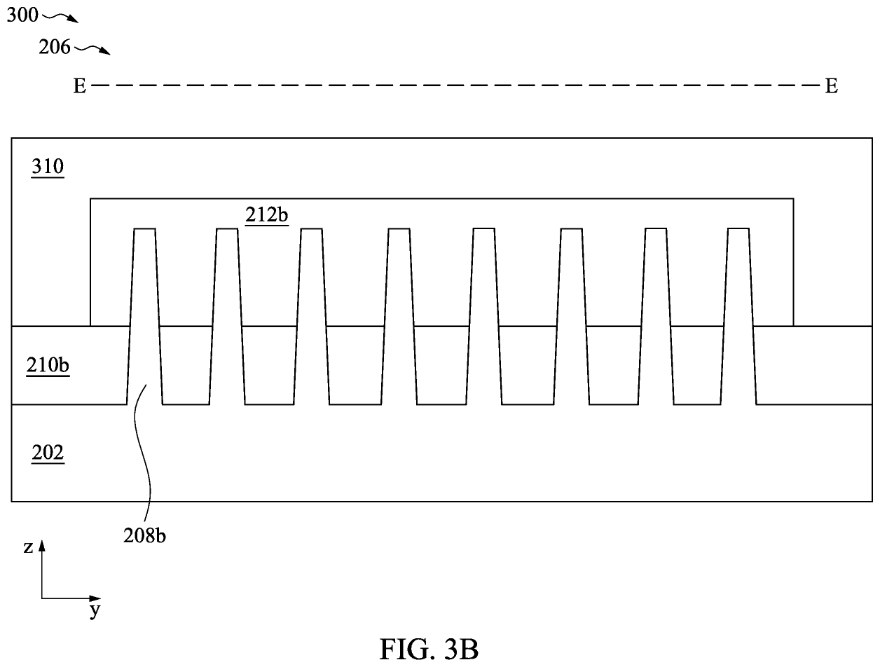

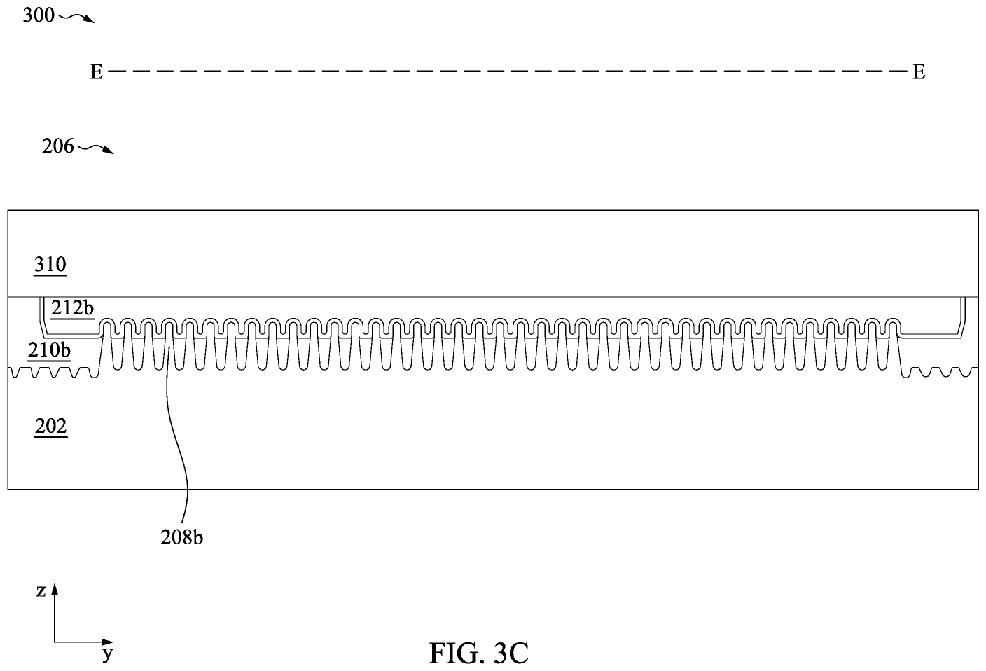

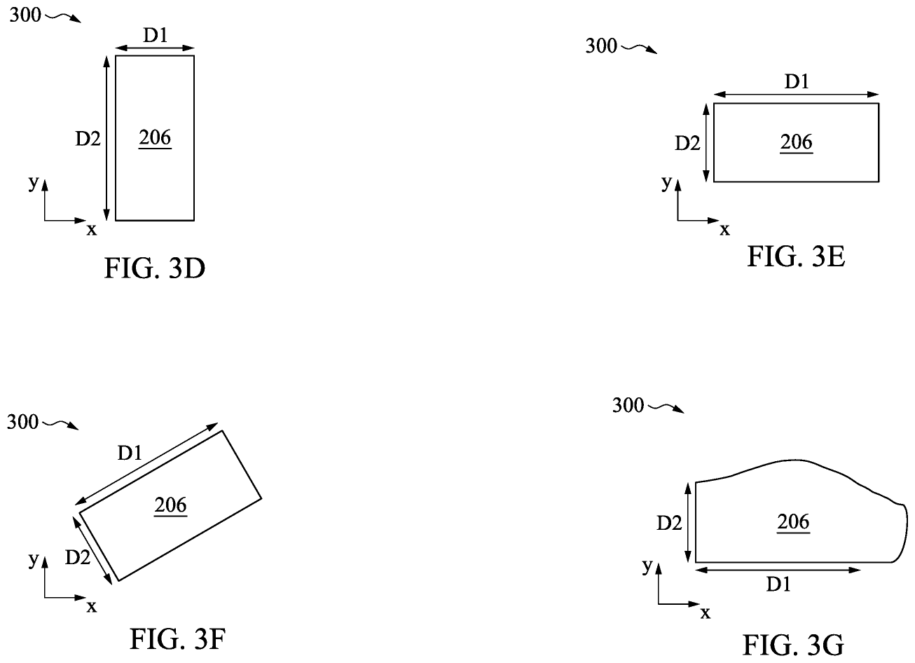

FIGS. 3A-3C are diagrams of an example implementation 300 of an alignment mark region 206 (or portion thereof) that may be included in a semiconductor device 200 described herein.

FIG. 3A illustrates top-down views of the example implementation 300 of the alignment mark region 206. As shown in FIG. 3A, the alignment mark region 206 may include a dimension D1 corresponding to a length of the alignment mark region 206. In some implementations, dimension D1 is included in a range of approximately 30 microns to approximately 300 microns. However, other values for the range are within the scope of the present disclosure. The alignment mark region 206 may include a dimension D2 corresponding to a width of the alignment mark region 206. In some implementations, dimension D2 is included in a range of approximately 30 microns to approximately 300 microns. However, other values for the range are within the scope of the present disclosure. In some implementations, a ratio of the dimension D2 to the dimension D1 may be included in a range of approximately 1:1 to approximately 100:1. However, other values for the range are within the scope of the present disclosure. In some implementations, a ratio of the dimension D1 to the dimension D2 may be included in a range of approximately 1:1 to approximately 100:1. However, other values for the range are within the scope of the present disclosure.

As further shown in FIG. 3A, the alignment mark region 206 may include a plurality of fin structures 208b that extend in a first direction (e.g., an x-direction) in the semiconductor device 200. The alignment mark region 206 may further include a plurality of dummy gate structures 212b that extend in a second direction (e.g., a y-direction) in the semiconductor device 200 over at least a subset of the fin structures 208b. The first direction and the second direction may be approximately perpendicular, and therefore the fin structures 208b and the dummy gate structures 212b may be approximately perpendicular in the alignment mark region 206.

As indicated above, a replacement gate process may be performed to replace the dummy gate structures 212b with metal gate structures. Accordingly, the metal gate structures in the alignment mark region 206 in the final structure of the semiconductor device 200 may conform to the arrangement and properties of the pattern 302 and the dummy gate structures 212b described in connection with FIGS. 3A-3G. The dummy gate structures 212b (and therefore, the metal gate structures that replace the dummy gate structures 212b) may have a dimension D3 and a dimension D4. The dimension D3 may correspond to a length of a dummy gate structure 212b. The dimension D4 may correspond to a width of a dummy gate structure 212b. In some implementations, the dimension D3 may be included in a range of approximately 1,000 nanometers to approximately 4,000 nanometers. However, other values for the range are within the scope of the present disclosure. In some implementations, the dimension D4 may be included in a range of approximately 100 nanometers to approximately 300 nanometers. However, other values for the range are within the scope of the present disclosure.

The alignment mark region 206 may include a pattern 302 that is formed from the arrangement of dummy gate structures 212b in the alignment mark region 206. Therefore, the pattern 302 in the alignment mark region 206 may be referred to as a polysilicon gate based alignment pattern or a dummy gate based alignment pattern. The pattern 302 may include a plurality of angular rows 304 and 306 that are spaced apart by gaps 308. The rows 304 and 306 may extend in an xy-direction in the alignment mark region 206 such that the rows 304 and 306 are diagonal to the fin structures 208b. Thus, the rows 304 and 306 may extend in a non-perpendicular direction relative to a direction (x-direction) in which the fin structures 208b (e.g., the non-active fin structures) extend. The rows 304 may include non-intersecting rows, whereas the rows 306 may include a plurality of rows 304 that intersect, thereby forming approximately chevron-shaped rows 306 that are separated by approximately chevron-shaped gaps 308.

The pattern 302 may be formed by forming the dummy gate structures 212b such that the dummy gate structures 212b extend in the second direction (e.g., the y-direction), and then etching portions of the dummy gate structures 212b to remove the portions of the dummy gate structures 212b, which results in formation of the gaps 308 between the rows 304, 306. The dummy gate structures 212b may be etched such that ends of the dummy gate structures 212b in the same row 304 or 306 are staggered or offset in the first direction (e.g., the x-direction) by an offset distance O1. The dummy gate structures 212b in a row 304 or 306 may be spaced apart by a gap 308 from the dummy gate structures 212b in an adjacent row 304 or 306 by a dimension D5. The dummy gate structures 212b in the same row 304 or 306 may be spaced apart by a dimension D6. In some implementations, the gate spacing (e.g., the dimensions D5 and D6) of the dummy gate structures 212b in the alignment mark region 206 may be approximately the same as the gate spacing of the dummy gate structures 212a in the active device region(s) of the semiconductor device 200. This may result from the dummy gate structures 212a and the dummy gate structures 212b being formed in the same set of semiconductor processes.

FIGS. 3B and 3C illustrate cross-sectional views along the cross-section E-E in FIGS. 2B and 3A. As shown in FIGS. 3B and 3C, a dummy gate structure 212b may extend across a plurality of fin structures 208b in the alignment mark region 206. The dummy gate structure 212b may be covered by a dielectric layer 310. The dielectric layer 310 may correspond to an interlayer dielectric (ILD) layer of the semiconductor device 200, such as an ILDO layer. In some implementations, the dielectric layer 310 may have a thickness that is included in a range of approximately 200 nanometers to approximately 5,000 nanometers. However, other values for the range are within the scope of the present disclosure. In some implementations, the dielectric layer 310 may have a thickness that is included in a range of approximately 200 nanometers to approximately 3,000 nanometers. However, other values for the range are within the scope of the present disclosure. The dielectric layer 310 may include an oxide-containing material, a nitride-containing material, and/or another type of dielectric material. The dielectric layer 310 may include dielectric material containing silicon (Si), hafnium (Hf), zirconium (Zr), lead (Pb), antimony (Sb), and/or lanthanum (La), among other examples.

The use of dummy gate structures 212b in the alignment mark region 206 may reduce the likelihood of and/or may prevent the pattern 302 from becoming obscured or covered by residual material byproducts from one or more semiconductor processing operations that are performed to form various layers and/or structures of the semiconductor device 200. For example, the use of dummy gate structures 212b in the alignment mark region 206 may enable a gate spacing parameter or design rule for the semiconductor device 200 to be satisfied in the alignment mark region 206. In particular, the dimensions D5 and D6 may satisfy a gate spacing parameter of having approximately 2 square microns of area or less between dummy gate structures 212b in the alignment mark region 206. This may reduce the likelihood of dishing in the dielectric layer 310, where the height of the dielectric layer 310 at the center of the alignment mark region 206 is less than the height of the dielectric layer 310 at the perimeter of the alignment mark region. The dishing may be prevented (or the magnitude of dishing may be minimized) in that the close spacing of dummy gate structures 212b in the alignment mark region 206 may prevent or reduce the magnitude of polishing pad deformation of the planarization tool 110 when the planarization tool 110 is used to planarize the dielectric layer 310 (e.g., as part of the replacement gate process). The reduced magnitude or prevention of the dishing in the dielectric layer 310 may reduce the likelihood of and/or prevent residual metal material and/or other material, that is deposited as part of the replacement gate process to form the metal gate structures of the semiconductor device 200, from being retained above the dielectric layer 310 in the alignment mark region 206. Accordingly, the polysilicon gate based alignment pattern or dummy gate based alignment pattern of the alignment mark region 206 in the example implementation 300 may reduce the likelihood of and/or prevent residual metal material and/or other material from obscuring or blocking the pattern 302 in the alignment mark region 206.

FIGS. 3D-3G illustrate various top-down shapes and/or arrangements for the alignment mark region 206. In FIG. 3D, the dimension D2 in the y-direction is greater relative to the dimension D1 in the x-direction. In FIG. 3E, the dimension D1 in the x-direction is greater relative to the dimension D2 in the y-direction. In FIG. 3F, the alignment mark region 206 is rotated such that the dimensions D1 and D2 are in an xy-direction in the semiconductor device 200. In FIGS. 3A-3F, the alignment mark region 206 includes a substantially rectangular shape. Alternatively, the alignment mark region 206 may include a substantially square shape, a substantially triangular shape, a substantially circular shape, and/or another shape. Moreover, in some implementations, the alignment mark region 206 may include an irregular shape, as shown in FIG. 3G. In general, the alignment mark region 206 may be sized, shaped, and/or orientated to suit placement of the alignment mark region 206 in the semiconductor device 200 layout and to accommodate the layout and/or arrangement of active device regions 204 in the semiconductor device 200 layout.

As indicated above, FIGS. 3A-3C are provided as an example. Other examples may differ from what is described with regard to FIGS. 3A-3C.

FIGS. 4A-4D are diagrams of an example implementation 400 described herein. The example implementation 400 includes an example of forming fin structures 208a and 208b for an active device region 204 and for the alignment mark region 206 of the semiconductor device 200. FIGS. 4A-4D are illustrated from the perspective of the cross-sectional plane C-C in FIG. 2B for the active device region 204, and from the perspective of the cross-sectional plane D-D in FIG. 2B for the alignment mark region 206. In some implementations, the alignment mark region 206 may be masked during the fin formation process so that only fin structures 208a are formed in the active device region 204, and so that fin structures 208b are omitted from the alignment mark region 206.

Turning to FIG. 4A, the example implementation 400 includes semiconductor processing operations relating to the substrate 202 in and/or on which transistors may be formed in the active device region 204, and in and/or on which a pattern 302 in the alignment mark region 206 may be formed.

As shown in FIG. 4B, fin structures 208a and 208b are formed in active device region 204 and in the alignment mark region 206, respectively, in the substrate 202. In particular, one or more fin structures 208a are formed in active device region 204 in the substrate 202, and one or more fin structures 208b are formed in the alignment mark region 206 in the substrate 202.

In some implementations, a pattern in a photoresist layer is used to form the fin structures 208a and 208b. In these implementations, a deposition tool 102 is used to form the photoresist layer on the substrate 202. An exposure tool 104 is used to expose the photoresist layer to a radiation source to pattern the photoresist layer. A developer tool 106 is used to develop and remove portions of the photoresist layer to expose the pattern. An etch tool 108 is used to etch into the substrate 202 to form the fin structures 208a and 208b. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the fin structures 208a and 208b based on a pattern.

As shown in FIG. 4C, an STI layer 210 is formed in between the fin structures 208a and 208b. A deposition tool 102 is used to deposit the STI layer 210 using a CVD technique, a PVD technique, an ALD technique, a deposition technique described above in connection with FIG. 1, and/or another deposition technique. In some implementations, the STI layer 210 is formed to a height that is greater than the height of the fin structures 208a and 208b. In these implementations, a planarization tool 110 is used to perform a planarization (or polishing) operation to planarize the STI layer 210 such that the top surface of the STI layer 210 is substantially flat and smooth, and such that the top surface of the STI layer 210 and the top surface of the fin structures 208a and 208b are approximately the same height. The planarization operation may increase uniformity in the STI regions 210a and 210b that are formed in a subsequent etch-back operation.

As shown in FIG. 4D, the STI layer 210 is etched in an etch back operation to expose portions of the fin structures 208a and 208b. An etch tool 108 is used to etch a portion of the STI layer 210 using a plasma etch technique, a wet chemical etch technique, and/or another type of etch technique. The remaining portions of the STI layer 210 between the fin structures 208a include the STI regions 210a, and the remaining portions of the STI layer 210 between the fin structures 208b include the STI regions 210b. In some implementations, the STI layer 210 is etched such that the height of the exposed portions of the fin structures 208a (e.g., the portions of the fin structures 208a that are above the top surface of the STI regions 210a) and the height of the exposed portions of the fin structures 208b (e.g., the portions of the fin structures 208b that are above the top surface of the STI regions 210b) are the same height. In some implementations, the STI layer 210 is etched such that the height of the exposed portions of the fin structures 208a and the height of the exposed portions of the fin structures 208b are different.

As indicated above, FIGS. 4A-4D are provided as an example. Other examples may differ from what is described with regard to FIGS. 4A-4D.

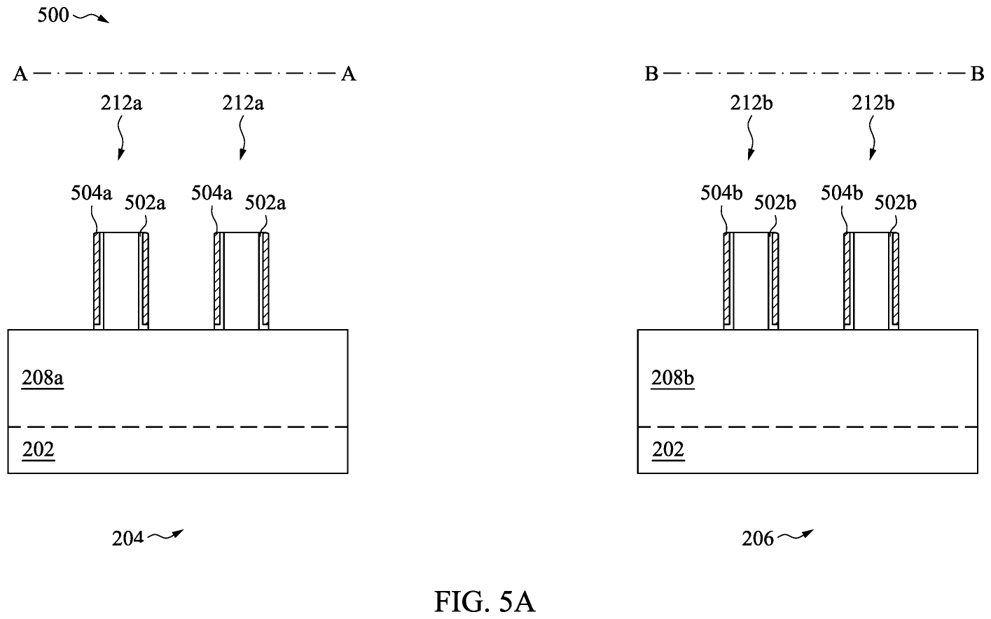

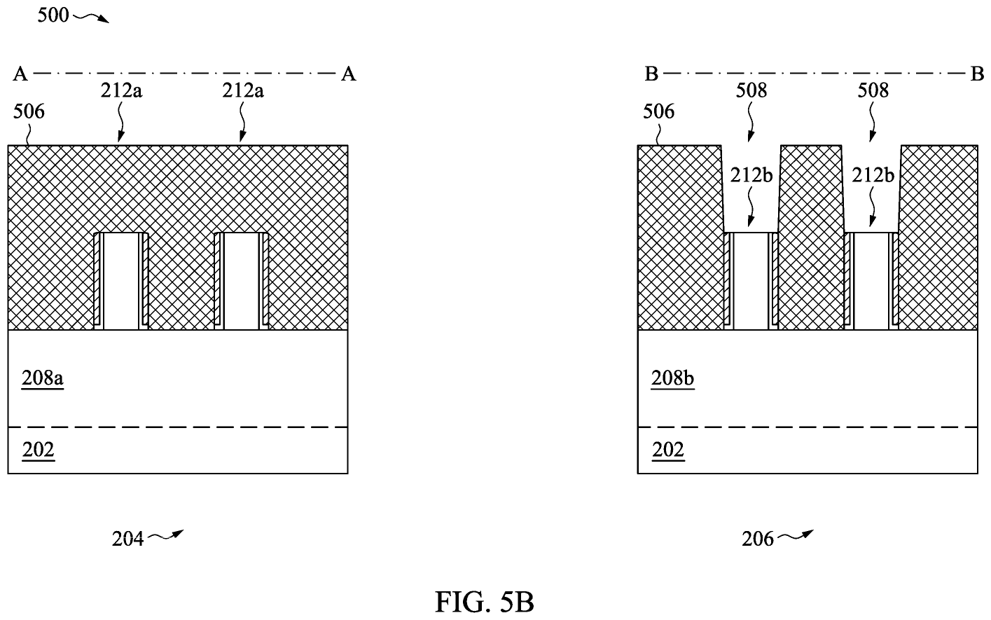

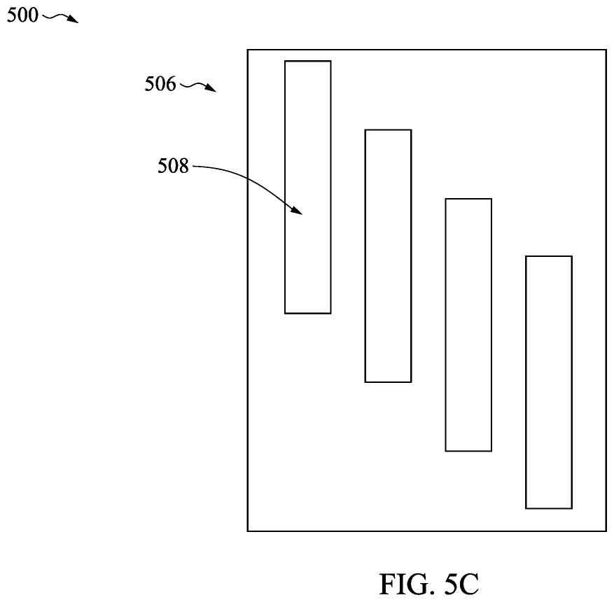

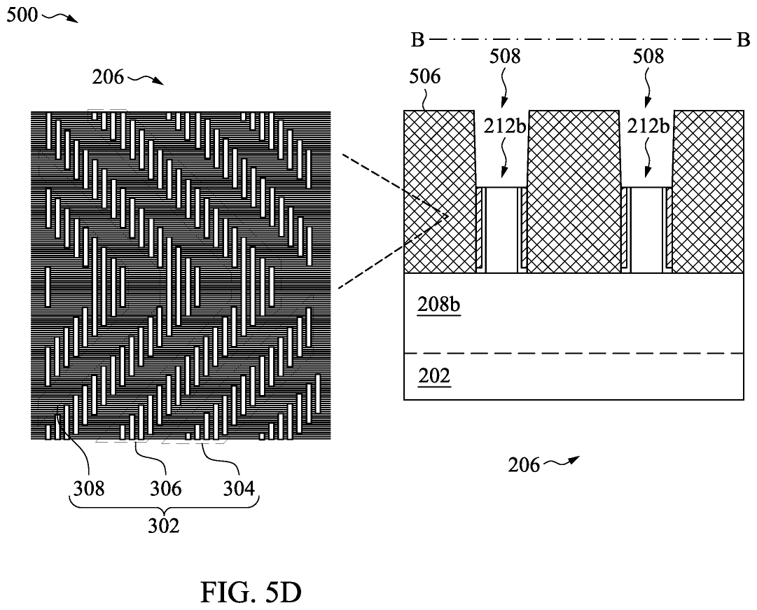

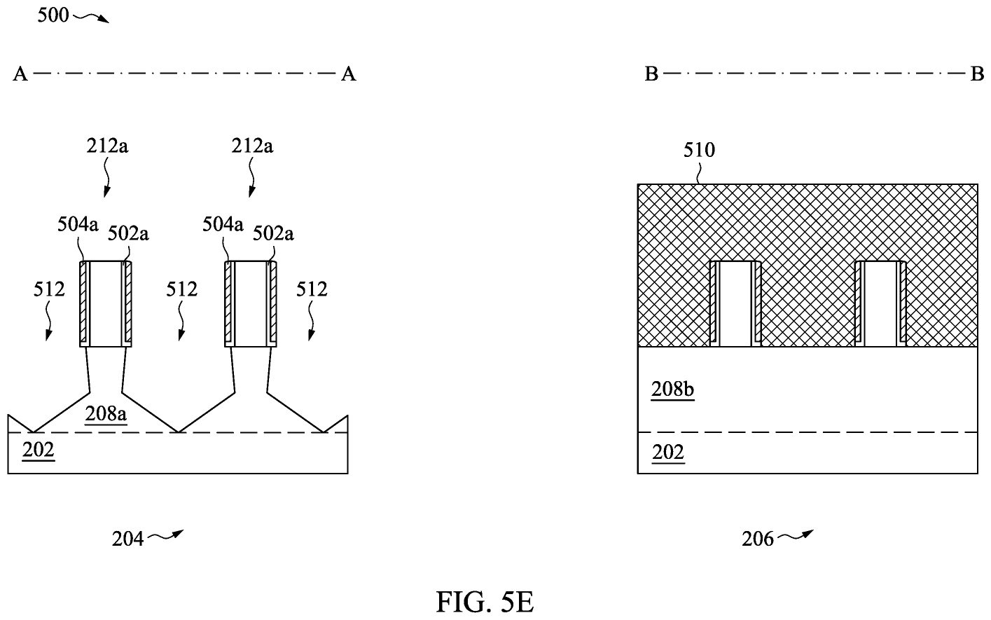

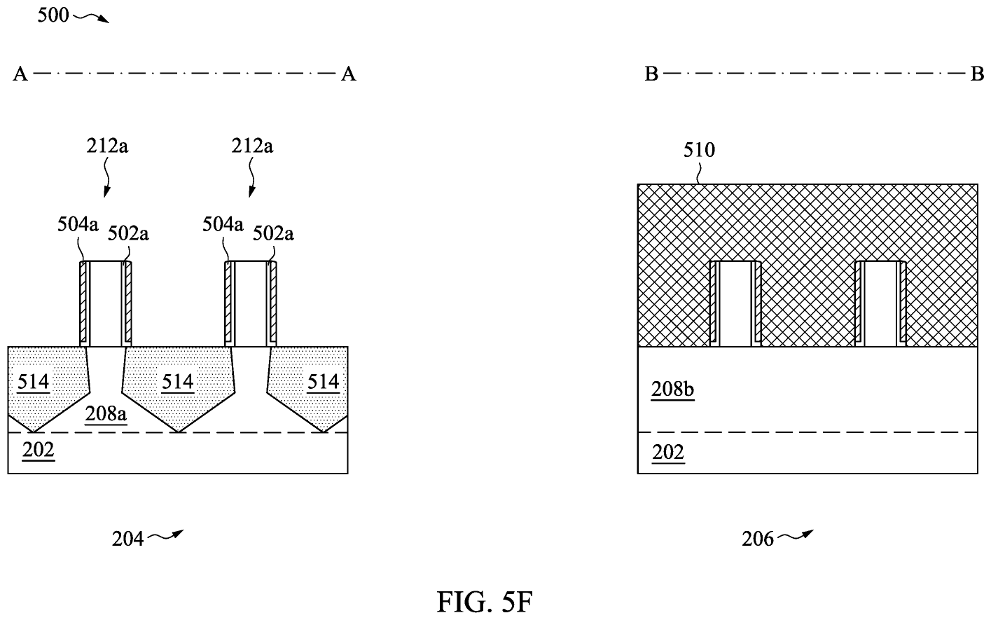

FIGS. 5A-5F are diagrams of an example implementation 500 described herein. The example implementation 500 includes an example of forming dummy gate structures 212a and 212b, forming a pattern 302 from the dummy gate structures 212b in the alignment mark region 206, and forming source/drain regions in the source/drain areas 214 of the active device region 204. FIGS. 5A-5F are illustrated from the perspective of the cross-sectional plane A-A in FIG. 2B for the active device region 204, and from the perspective of the cross-sectional plane B-B in FIG. 2B for the alignment mark region 206. In some implementations, the operations described in connection with the example implementation 500 are performed after the fin formation process described in connection with FIGS. 4A-4D.

As shown in FIG. 5A, dummy gate structures 212a are formed in the active device region 204 and dummy gate structures 212b are formed in the alignment mark region 206. The dummy gate structures 212a are formed and included over the fin structures 208a, and around the sides of the fin structures 208a such that the dummy gate structures 212a surround the fin structure 208a on at least three sides of the fin structure 208a. The dummy gate structures 212b are formed and included over the fin structure 208b, and around the sides of the fin structure 208b such that the dummy gate structures 212b surround the fin structure 208b on three sides of the fin structure 208b. The dummy gate structures 212a and 212b may each include a polysilicon layer and/or other suitable layers. The dummy gate structures 212a and 212b may be formed (e.g., using the deposition tool 102) by suitable deposition processes such as LPCVD or PECVD, among other examples.

The dummy gate structures 212a and 212b are formed as placeholders for the actual gate structures (e.g., replacement high-k gate or metal gate) that are to be formed in the active device region 204 and in the alignment mark region 206, respectively. The dummy gate structures 212a and 212b may be replaced as part of a replacement gate process, which enables other layers and/or structures to be formed prior to formation of the replacement gate structures.

As further shown in FIG. 5A, seal spacer layers 502a may be included on the sidewalls of the dummy gate structures 212a. Similarly, seal spacer layers 502b may be included on the sidewalls of the dummy gate structures 212b. The seal spacer layers 502a and 502b may be conformally deposited (e.g., using the deposition tool 102) and may include a silicon oxycarbide (SiOC), a nitrogen-free SiOC, or another suitable material. The seal spacer layers 502a and 502b may be formed in an ALD operation in which various types of precursor gases including silicon (Si) and carbon (C) are sequentially supplied in a plurality of alternating cycles to form the seal spacer layers 502a and 502b, among other example deposition techniques.

As further shown in FIG. 5A, bulk spacer layers 504a may be formed on the seal spacer layers 502a. Similarly, bulk spacer layers 504b may be formed on the seal spacer layers 502b. The bulk spacer layers 504a and 504b may be formed of similar materials as the seal spacer layers 502a and 502b. However, the bulk spacer layers 504a and 504b may formed without plasma surface treatment that is used for the seal spacer layers 502a and 502b. Moreover, the bulk spacer layers 504a and 504b may be formed to a greater thickness relative to the thickness of the seal spacer layers 502a and 502b.

In some implementations, the seal spacer layers 502a and 502b and the bulk spacer layers 504a and 504b are conformally deposited (e.g., using the deposition tool 102) on the dummy gate structures 212a and 212b respectively, and on the fin structures 208a and 208b respectively. The seal spacer layers 502a and 502b, and the bulk spacer layers 504a and 504b, are then patterned (e.g., using the deposition tool 102, the exposure tool 104, and the developer tool 106) and etched (e.g., using the etch tool 108) to remove the seal spacer layers 502a and 502b and the bulk spacer layers 504a and 504b from the tops of the dummy gate structures 212a and 212b respectively, and from the fin structures 208a and 208b respectively.

As shown in FIG. 5B, a photoresist layer 506 is formed over and/or on the fin structures 208a, over and/or on the dummy gate structures 212a, over and/or on the fin structures 208b, and over and/or on the dummy gate structures 212b. The photoresist layer 506 may further be formed over the STI regions 210a (e.g., the exposed portions of the STI regions 210a) and over the STI regions 210b (e.g., the exposed portions of the STI regions 210b). The deposition tool 102 may be used to form the photoresist layer 506 using a spin-coating technique or another deposition technique. The photoresist layer 506 is formed to protect the fin structures 208a, the STI regions 210a, the dummy gate structures 212a, the fin structures 208b, the STI regions 210b, and portions of the dummy gate structures 212b in a subsequent etch operation in which other portions of the dummy gate structures 212b are etched to form the pattern 302 (e.g., the dummy gate based alignment pattern or polysilicon based alignment pattern) in the alignment mark region 206.

As shown in FIGS. 5B and 5C, a pattern 508 may be formed in the photoresist layer 506 over the dummy gate structures 212b in the alignment mark region 206. The pattern 508 may include openings in the photoresist layer 506 over the dummy gate structures 212b through which portions of the dummy gate structures 212b are exposed through the photoresist layer 506. An exposure tool 104 may be used to expose the photoresist layer 506 to a radiation source to form the pattern 508 in the photoresist layer 506. A developer tool 106 is used to develop and remove portions of the photoresist layer 506 to expose the pattern 508.

As shown in FIG. 5D, an etch tool 108 is used to etch portions of the dummy gate structures 212b exposed through the pattern 508 in the photoresist layer 506 to remove the exposed portions of the dummy gate structures 212b. In some implementations, the etch operation includes a plasma etch technique, a wet chemical etch technique, and/or another type of etch technique. Removal of the exposed portions of the dummy gate structures 212b results in formation of the pattern in the alignment mark region 206, which may include a plurality of rows 304, 306 of dummy gate structures 212b spaced apart by gaps 308. In some implementations, a photoresist removal tool removes the remaining portions of the photoresist layer (e.g., using a chemical stripper, plasma ashing, and/or another technique) after formation of the pattern 302.

As shown in FIG. 5E, a masking layer 510 is formed over and/or on the fin structures 208b and over and/or on the dummy gate structures 212b. The masking layer 510 may further be formed over the STI regions 210b (e.g., the exposed portions of the STI regions 210b). The deposition tool 102 may be used to form the masking layer 510 using a spin-coating technique or another deposition technique. The masking layer 510 is formed to protect the fin structures 208b, the STI regions 210b, and the dummy gate structures 212b in a subsequent etch operation in which recesses for the source/drain regions of the transistors in the active device region 204 are partially etched. Moreover, the masking layer 510 is formed to protect the fin structures 208b, the STI regions 210b, and the dummy gate structures 212b in a subsequent epitaxial growth operation in which the source/drain regions of the transistors in the active device region 204 are formed in the recesses.

As further shown in FIG. 5E, recesses 512 are formed in the fin structures 208a in the active device region 204 between the dummy gate structures 212a in an etch operation. The etch operation may be referred to a strained source/drain (SSD) etch operation, and the recesses 512 may be referred to as strained source/drain regions. The etch tool 108 may be used to form the recesses 512 after the masking layer 510 is formed. In this way, the masking layer 510 protects the fin structure 208b and other structures in the active device region 204 from being etched in the etch operation. In some implementations, the etch operation includes a plasma etch technique, a wet chemical etch technique, and/or another type of etch technique.

As shown in FIG. 5F, source/drain regions 514 are formed in the recesses 512 in the active device region 204 of the semiconductor device 200 over the substrate 202. The deposition tool 102 may be used to form the source/drain regions 514 using an epitaxial growth technique, in which layers of the epitaxial material are deposited in the recesses 512 such that the layers of the source/drain regions 514 are formed by epitaxial growth in a particular crystalline orientation. The source/drain regions 514 are included between the dummy gate structures 212a and at least partially below and/or lower than the dummy gate structures 212a. The source/drain regions 514 may partially extend above the top surface of the fin structures 208a.

The material (e.g., silicon (Si), gallium (Ga), or another type of semiconductor material) that is used to form the source/drain regions 514 may be doped with a p-type dopant (e.g., a type of dopant that includes electron acceptor atoms that create holes in the material), an n-type dopant (e.g., a type of dopant that includes hole acceptor atoms that create electrons in the material), and/or another type of dopant. The material may be doped by adding impurities (e.g., the p-type dopant or the n-type dopant) to a source gas that is used during the epitaxial operation.

As indicated above, FIGS. 5A-5F are provided as an example. Other examples may differ from what is described with regard to FIGS. 5A-5F.

FIGS. 6A-6G are diagrams of an example implementation 600 described herein. The example implementation 600 includes an example replacement gate process, in which the dummy gate structures 212a and 212b are replaced with metal gate structures that include high-k and/or metal layers. FIGS. 6A-6G are illustrated from the perspective of the cross-sectional plane A-A in FIG. 2B for the active device region 204, and from the perspective of the cross-sectional plane B-B in FIG. 2B for the alignment mark region 206.

As shown in FIG. 6A, a contact etch stop layer (CESL) 602a is conformally deposited (e.g., using a deposition tool 102) over the source/drain regions 514, over the dummy gate structures 212a, and on the sidewalls of the bulk spacer layers 504a. Similarly, a CESL 602b is conformally deposited (e.g., using a deposition tool 102) over the fin structures 208b, over the STI regions 210b, over the dummy gate structures 212b, and on the sidewalls of the bulk spacer layers 504b. The CESLs 602a and 602b may provide a mechanism to stop a planarization operation when planarizing an ILD layer that is formed over the dummy gate structures 212a and 212b as part of the replacement gate process. The CESLs 602a and 602b may be formed of a dielectric material having a different etch selectivity from adjacent layers or components. The CESLs 602a and 602b may include or may be a nitrogen containing material, a silicon containing material, and/or a carbon containing material. Furthermore, the CESLs 602a and 602b may include or may be silicon nitride, silicon carbon nitride, carbon nitride, silicon oxynitride, silicon carbon oxide, or a combination thereof, among other examples. The CESLs 602a and 602b may be deposited (e.g., using a deposition tool 102) by a deposition process, such as ALD, CVD, or another deposition technique.

As shown in FIG. 6B, an ILD layer 604a is formed (e.g., using a deposition tool 102) over and/or on the CESL 602a. The ILD layer 604a fills in the areas between the dummy gate structures 212a over the source/drain regions 514. An ILD layer 604b is formed (e.g., using a deposition tool 102) over and/or on the CESL 602b. The ILD layer 604b fills in the areas between the dummy gate structures 212b. The ILD layer 604b may correspond to the dielectric layer 310. The ILD layers 604a and 604b are formed to permit a replacement gate structure process to be performed in the active device region 204 and in the alignment mark region 206, respectively, in which metal gate structures are formed to replace the dummy gate structures 212a and 212b.

In some implementations, the ILD layer 604a is formed to a height (or thickness) such that the ILD layer 604a covers the dummy gate structures 212a, as shown in the example in FIG. 6B. Similarly, the ILD layer 604b may be formed to a height (or thickness) such that the ILD layer 604b covers the dummy gate structures 212b, as shown in the example in FIG. 6B.

As shown in FIGS. 6C and 6D, one or more planarization operations (e.g., a CMP operation performed using a planarization tool 110) are performed to planarize the ILD layers 604a and 604b and the CESLs 602a and 602b such that the top surfaces of the ILD layers 604a and 604b are approximately at a same height as the top surfaces of the dummy gate structures 212a and 212b, respectively. In this way, the one or more planarization operations are performed to expose the tops of the dummy gate structures 212a and 212b through the ILD layers 604a and 604b and the CESLs 602a and 602b. This enables the dummy gate structures 212a and 212b to be removed by etching.

As shown in FIG. 6C, a first planarization operation is performed to planarize the ILD layers 604a and 604b, and the planarization operation stops on the CESLs 602a and 602b. A planarization tool 110 may be used to planarize the ILD layers 604a and 604b in the first planarization. As described above, the use of dummy gate structures 212b in the alignment mark region 206 may enable a gate spacing parameter or design rule for the semiconductor device 200 to be satisfied in the alignment mark region 206. This may reduce the likelihood of dishing in the ILD layer 604b. The dishing may be prevented (or the magnitude of dishing may be minimized) in that the close spacing of dummy gate structures 212b in the alignment mark region 206 may prevent or reduce the magnitude of polishing pad deformation of a planarization tool 110 when the planarization tool 110 is used to planarize the ILD layer 604b in the first planarization operation.

As shown in FIG. 6D, a second planarization operation is performed after the first planarization operation. The second planarization operation may be performed to open CESLs 602a and 602b above the dummy gate structures 212a and 212b, respectively, to expose the dummy gate structures 212a and 212b. In some implementations, different planarization operations are performed for the ILD layers 604a and 604b and the CESLs 602a and 602b, as illustrated in the examples in FIGS. 6C and 6D, so that different polishing pads and/or different planarization parameters may be used for the first planarization operation and the second planarization operation. The different planarization parameters may include different polishing pad hardnesses, different polishing pad rotational speeds, and/or different magnitudes of downforce, among other examples.

As shown in FIGS. 6E and 6F, the dummy gate structures 212a are removed from the active device region 204 and the dummy gate structures 212b are removed from the alignment mark region 206. In some implementations, removal of the dummy gate structures 212b is omitted, and the dummy gate structures 212b are retained in the alignment mark region 206 for subsequent alignment-based processes. The removal of the dummy gate structures 212a leaves behind openings (or recesses) 606a between the bulk spacer layers 504a and between the source/drain regions 514. The removal of the dummy gate structures 212b leaves behind openings (or recesses) 606b between the bulk spacer layers 504b.

As further shown in FIGS. 6E and 6F, the dummy gate structures 212a and 212b may be removed in a plurality of etch operations. As shown in FIG. 6E, first portions of the dummy gate structures 212a and 212b may be removed in a dry etch operation using an etch tool 108. As shown in FIG. 6F, the remaining portions of the dummy gate structures 212a and 212b may be removed in a wet etch operation using an etch tool 108.

As shown in FIG. 6G, the replacement gate operation continues where a deposition tool 102 and/or a plating tool 112 forms the gate structures (e.g., replacement gate structures) 608a in the openings 606a between the bulk spacer layers 504a and between the source/drain regions 514, and forms gate structures 608b in the openings 606b between the bulk spacer layers 504b. The gate structures 608a and 608b may each include metal gate structures, high-k gate structures, or other types of gate structures. The gate structures 608a may be referred to as “active” gate structures in that the gate structures 608a are included in the functional transistors in the active device region 204. The gate structures 608b may be referred to as “non-active” gate structures in that the gate structures 608b are not to be used in the active devices of the semiconductor device 200 and instead are used for alignment purposes.

As indicated above, FIGS. 6A-6G are provided as an example. Other examples may differ from what is described with regard to FIGS. 6A-6G.

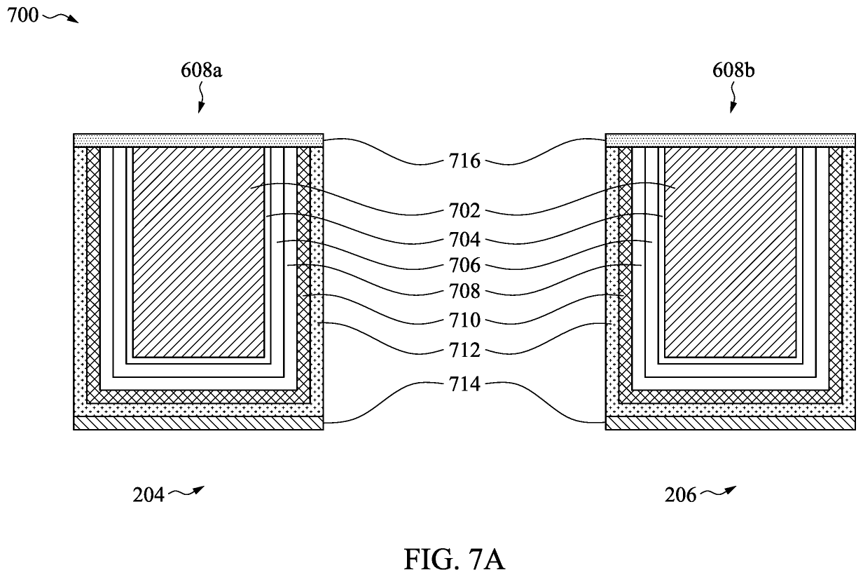

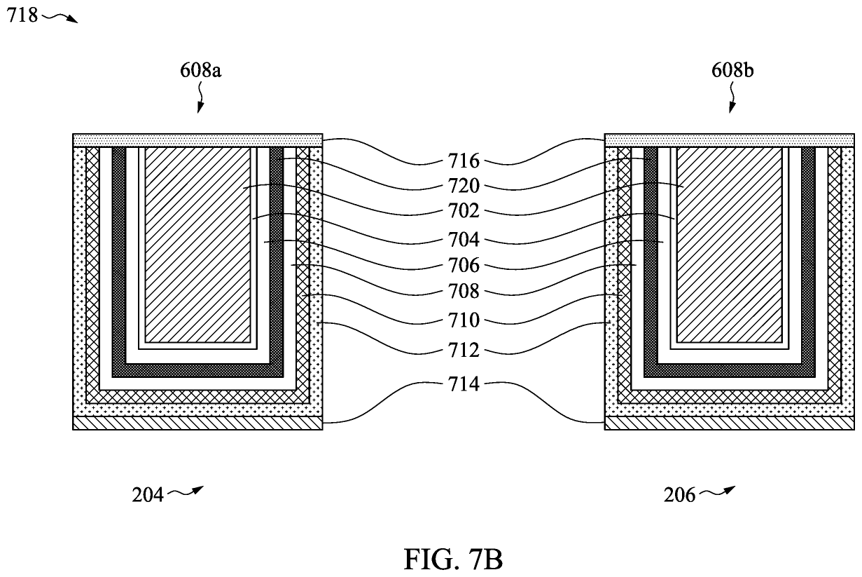

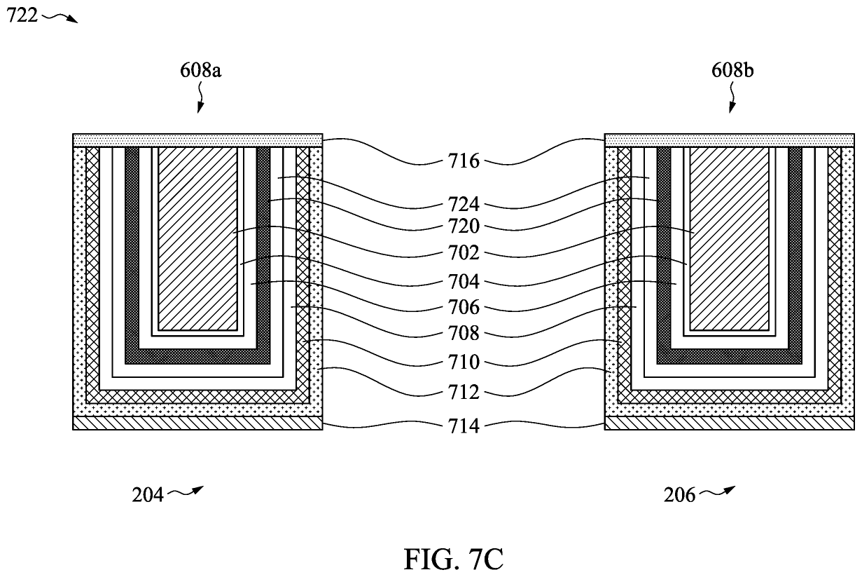

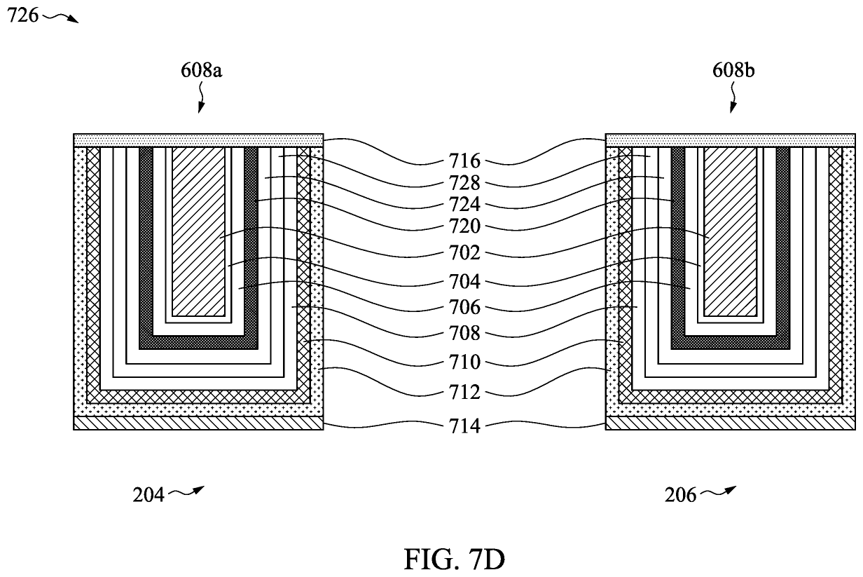

FIGS. 7A-7D are diagrams of example implementations of active gate structures and non-active gate structures described herein. “Active gate structures” may refer to gate structures 608a included in an active device region 204 of a semiconductor device 200 described herein. “Non-active gate structures” may refer to gate structures 608b included in an alignment mark region 206 of a semiconductor device 200 described herein.

FIG. 7A illustrates an example implementation 700 of gate structures 608a included in the active device region 204 and gate structures 608b included in the alignment mark region 206. As shown in FIG. 7A, a gate structure 608a and a gate structure 608b may each include a plurality of layers. For example, the gate structure 608a and the gate structure 608b may each include a metal electrode 702, a glue layer 704 surrounding three sides of the metal electrode 702, a work function metal (WFM) layer 706 (e.g., where the glue layer 704 adheres the WFM layer 706 to the metal electrode 702), a barrier layer 708, a capping layer 710, a high-k dielectric layer 712, an interfacial layer (IL) 714, and a capping layer 716, among other examples. The WFM layer 706 may be included between the glue layer 704 and the barrier layer 708. The barrier layer 708 may be included between the WFM layer 706 and the capping layer 710. The capping layer 710 may be included between the barrier layer 708 and the high-k dielectric layer 712. The high-k dielectric layer 712 may be included between the capping layer 710 and the interfacial layer 714. An interfacial layer 714 may be included between the gate structure 608a and an underlying fin structure 208b. An interfacial layer 714 may be included between the gate structure 608b and an underlying fin structure 208b. A capping layer 716 may be included on the gate structure 608a, and another capping layer 716 may be included on the gate structure 608b.

The metal electrode 702 may include tungsten (W) and/or another conductive metal. The glue layer 704 may include titanium nitride (TiN) and/or another adhesion material. The thickness of the glue layer 704 may be included in a range of approximately 20 angstroms to approximately 40 angstroms. However, other values for the range are within the scope of the present disclosure.

The WFM layer 706 may include titanium (Ti), aluminum (Al), tantalum (Ta), zirconium (Zr), zinc (Zn), an alloy thereof, and/or another material. The thickness of the WFM layer 706 may be included in a range of approximately 40 angstroms to approximately 60 angstroms. However, other values for the range are within the scope of the present disclosure.

The barrier layer 708 may include tantalum nitride (TaN) and/or another barrier layer material. The thickness of the barrier layer 708 may be included in a range of approximately 5 angstroms to approximately 20 angstroms. However, other values for the range are within the scope of the present disclosure.

The capping layer 710 may include titanium nitride (TiN) and/or another capping layer material. The high-k dielectric layer 712 may include one or more high-k dielectric materials, such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), yttrium titanium oxide (YₓTiO_{y} such as Y₂TiO₅), hafnium oxide (HfOₓ such as HfO₂), and/or tantalum oxide (TaₓO_{y} such as Ta₂O₅), among other examples. The interfacial layer 714 may include an oxide-containing dielectric material (e.g., silicon oxide (SiOₓ)), a nitride-containing dielectric material (e.g., silicon nitride (SiₓN_{y})), and/or another suitable material. The capping layer 716 may include an oxide-containing dielectric material (e.g., silicon oxide (SiOₓ)), a nitride-containing dielectric material (e.g., silicon nitride (SiₓN_{y})), and/or another suitable material.

The combination and/or arrangement of layers for the gate structures 608a and for the gate structures 608b included in the example implementation 700 may be used where the transistors of the active device region 204 include n-type low threshold voltage transistors (N-LVT) or n-type ultra-low threshold voltage transistors (N-uLVT). This enables full process integration of the formation of the gate structures 608a and the gate structures 608b.

FIG. 7B illustrates an example implementation 718 of gate structures 608a included in the active device region 204 and gate structures 608b included in the alignment mark region 206. As shown in FIG. 7B, a gate structure 608a and a gate structure 608b may each include a plurality of layers similar to the combination and arrangement of layers 702-716 in the example implementation 700 of FIG. 7A. The gate structure 608a and the gate structure 608b may each include an additional WFM layer 720 in the example implementation 718 for further work function tuning. The WFM layer 720 may be included between the WFM layer 706 and the barrier layer 708, and may include an oxide and/or a nitride of titanium (Ti), aluminum (Al), tantalum (Ta), zirconium (Zr), zinc (Zn), and/or another material. In some implementations, a thickness of the WFM layer 720 is included in range of approximately 5 angstroms to approximately 15 angstroms. However, other values for the range are within the scope of the present disclosure.

The combination and/or arrangement of layers for the gate structures 608a and for the gate structures 608b included in the example implementation 718 may be used where the transistors of the active device region 204 include n-type standard threshold voltage transistors (N-SVT), n-type I/O transistors (N-IO), pass-gate (PG) transistors, and/or pull-down (PD) transistors, among other examples. This enables full process integration of the formation of the gate structures 608a and the gate structures 608b.

FIG. 7C illustrates an example implementation 722 of gate structures 608a included in the active device region 204 and gate structures 608b included in the alignment mark region 206. As shown in FIG. 7C, a gate structure 608a and a gate structure 608b may each include a plurality of layers similar to the combination and arrangement of layers 702-716 and 720 in the example implementation 718 of FIG. 7B. The gate structure 608a and the gate structure 608b may each include an additional WFM layer 724 in the example implementation 722 for further work function tuning. The WFM layer 724 may be included between the WFM layer 720 and the barrier layer 708. In some implementations, a thickness of the WFM layer 724 is included in range of approximately 10 angstroms to approximately 20 angstroms. However, other values for the range are within the scope of the present disclosure.

In some implementations, the WFM layer 724 may include an oxide and/or a nitride of titanium (Ti), aluminum (Al), tantalum (Ta), zirconium (Zr), zinc (Zn), and/or another material. In some implementations, the WFM layer 706, the WFM layer 720, and the WFM layer 724 may each include different materials selected from an oxide or a nitride of titanium (Ti), tantalum (Ta), chromium (Cr), nickel (Ni), molybdenum (Mo), copper (Cu), zirconium (Zr), zinc (Zn), iron (Fe), and/or tin (Sn), among other examples.

The combination and/or arrangement of layers for the gate structures 608a and for the gate structures 608b included in the example implementation 722 may be used where the transistors of the active device region 204 include p-type standard threshold voltage transistors (P-SVT), p-type I/O transistors (P-IO), and/or pull-down (PD) transistors, among other examples. This enables full process integration of the formation of the gate structures 608a and the gate structures 608b.

FIG. 7D illustrates an example implementation 726 of gate structures 608a included in the active device region 204 and gate structures 608b included in the alignment mark region 206. As shown in FIG. 7D, a gate structure 608a and a gate structure 608b may each include a plurality of layers similar to the combination and arrangement of layers 702-716, 720, and 724 in the example implementation 722 of FIG. 7C. The gate structure 608a and the gate structure 608b may each include an additional WFM layer 728 in the example implementation 726 for further work function tuning. The WFM layer 728 may be included between the WFM layer 724 and the barrier layer 708. In some implementations, a thickness of the WFM layer 728 is included in range of approximately 10 angstroms to approximately 20 angstroms. However, other values for the range are within the scope of the present disclosure.

In some implementations, the WFM layer 728 may include an oxide and/or a nitride of titanium (Ti), aluminum (Al), tantalum (Ta), zirconium (Zr), zinc (Zn), and/or another material. In some implementations, the WFM layer 706, the WFM layer 720, the WFM layer 724, and the WFM layer 728 may each include different materials selected from an oxide or a nitride of titanium (Ti), tantalum (Ta), chromium (Cr), nickel (Ni), molybdenum (Mo), copper (Cu), zirconium (Zr), zinc (Zn), iron (Fe), and/or tin (Sn), among other examples.

The combination and/or arrangement of layers for the gate structures 608a and for the gate structures 608b included in the example implementation 726 may be used where the transistors of the active device region 204 include p-type low threshold voltage transistors (P-LVT) and/or p-type ultra-low voltage threshold transistors (P-uLVT), among other examples. This enables full process integration of the formation of the gate structures 608a and the gate structures 608b.

As indicated above, FIGS. 7A-7D are provided as examples. Other examples may differ from what is described with regard to FIGS. 7A-7D.

FIGS. 8A-8C are diagrams of example regions of a semiconductor device 800 described herein. The semiconductor device 800 may include a semiconductor die, a semiconductor chiplet, and/or another type of semiconductor device that is manufactured on a substrate 202.

As shown in FIG. 8A, the semiconductor device 800 may be similar to the semiconductor device 200 and may include one or more active device regions 204 and one or more alignment mark regions 206. The layout, shape, quantity, and/or arrangement of active device regions 204 and alignment mark regions 206 illustrated in FIG. 8A is an example, and other layouts, shapes, quantities, and/or arrangements are within the scope of the present disclosure.

As shown in FIG. 8B, an active device region 204 of the semiconductor device 800 may include a similar arrangement of components as an active device region 204 of the semiconductor device 200, including the substrate 202, the fin structures 208a (e.g., active fin structures), the STI regions 210a, and the dummy gate structures 212a. The dummy gate structures 212a may be replaced with one or more metal gate structure (e.g., gate structures 608a) implementations described herein.

As further shown in FIG. 8B, the alignment mark region 206 of the semiconductor device 800 may include a similar arrangement of components as the alignment mark region 206 of the semiconductor device 200, including the substrate 202, the STI regions 210b, and the dummy gate structures 212b. The dummy gate structures 212b may be replaced with one or more metal gate structure (e.g., gate structures 608b) implementations described herein.

As shown in FIGS. 8B and 8C, the fin structures 208b (e.g., non-active fin structures) are omitted from the alignment mark region 206 of the semiconductor device 800, and the dummy gate structures 212b (and the subsequent gate structures 608b) are formed and included directly on the STI regions 210b. This may reduce process complexity for the alignment mark region 206. In this way, the pattern 302 in the dummy gate structures 212a is formed directly on the STI regions 210b, as shown in FIG. 8C.

As indicated above, FIGS. 8A-8C are provided as an example. Other examples may differ from what is described with regard to FIGS. 8A-8C.

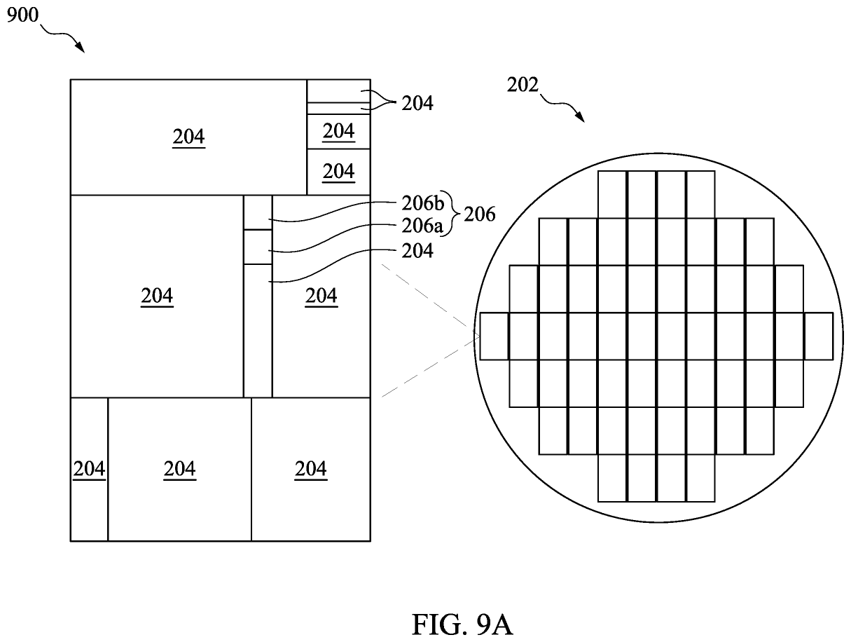

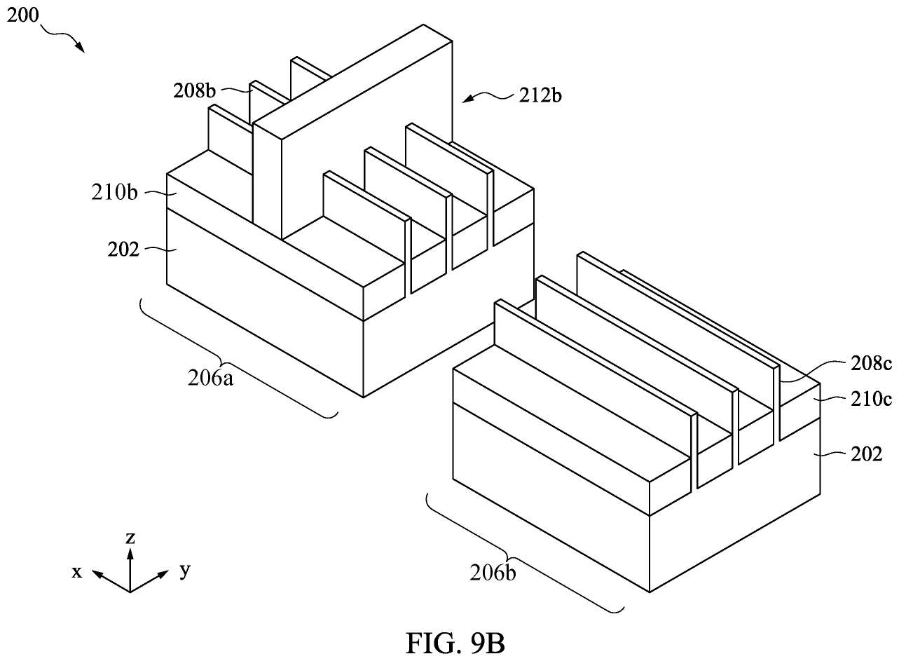

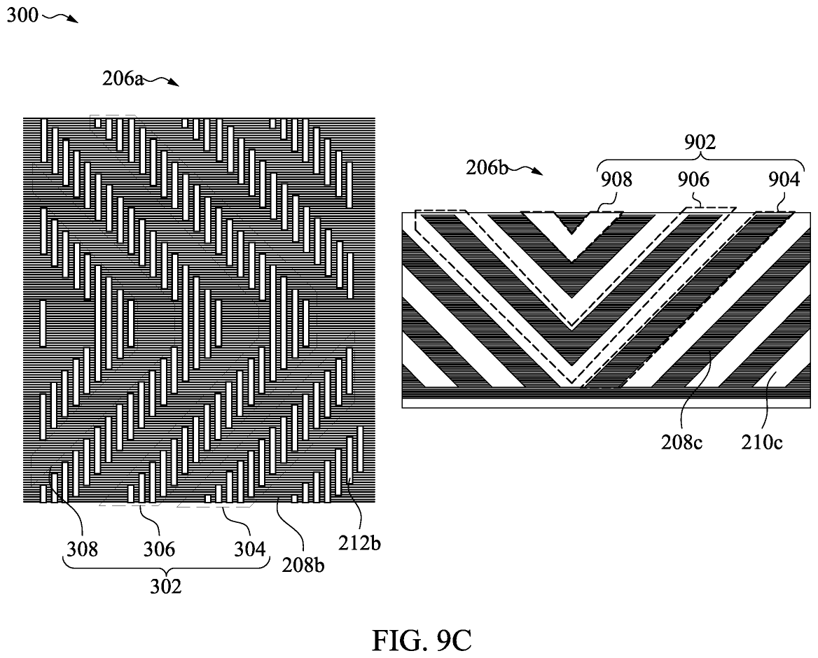

FIGS. 9A-9C are diagrams of example regions of a semiconductor device 900 described herein. The semiconductor device 900 may include a semiconductor die, a semiconductor chiplet, and/or another type of semiconductor device that is manufactured on a substrate 202.

As shown in FIG. 9A, the semiconductor device 900 may be similar to the semiconductor device 200 and may include one or more active device regions 204 and one or more alignment mark regions 206. The layout, shape, quantity, and/or arrangement of active device regions 204 and alignment mark regions 206 illustrated in FIG. 9A is an example, and other layouts, shapes, quantities, and/or arrangements are within the scope of the present disclosure.

As further shown in FIG. 9A, the semiconductor device 900 may include a plurality of alignment mark regions 206, including an alignment mark region 206a and an alignment mark region 206b. The alignment mark region 206b may be adjacent to the alignment mark region 206a in the top-down layout of the semiconductor device 900, may be adjacent to a subset of the one or more active device regions 204, and/or may be located in another location in the top-down layout of the semiconductor device 900.

As shown in FIG. 9B, the alignment mark region 206a of the semiconductor device 900 may include a similar arrangement of components of the alignment mark region 206 of the semiconductor device 200, including the substrate 202, the fin structures 208b (e.g., non-active fin structures), the STI regions 210b, and the dummy gate structures 212b. The dummy gate structures 212b may be replaced with one or more metal gate structure (e.g., gate structures 608a) implementations described herein. Thus, the alignment mark region 206a may be a polysilicon-gate-based alignment mark region or a dummy-gate-based alignment mark region.

As further shown in FIG. 9B, the alignment mark region 206b of the semiconductor device 900 may include a similar arrangement of components as the alignment mark region 206a, including the substrate 202, fin structures 208c (e.g., non-active fin structures), and STI regions 210c. However, the dummy gate structures may be omitted from the alignment mark region 206b. Thus, the alignment mark region 206b may be a fin based alignment mark region or an operation domain (OD) based alignment mark region.

As shown in FIG. 9C, the alignment mark region 206a may include a pattern 302 (e.g., a polysilicon-gate-based alignment mark pattern or a dummy-gate-based alignment mark pattern). The pattern 302 includes a plurality of dummy gate structures 212b (or gate structures 608b) over the fin structures 208b (e.g., non-active fin structures), where the dummy gate structures 212b are arranged in diagonal rows 304, 306 that are spaced apart by gaps 308.

As further shown in FIG. 9C, the alignment mark region 206b may include a pattern 902 (e.g., a fin based alignment mark pattern or an OD based alignment mark pattern). The pattern 902 includes a plurality of fin structures 208c (e.g., non-active fin structures) over the STI regions 210c, where the fin structures 208c are arranged in diagonal rows 904, 906 that are spaced apart by gaps 908. The fin structures 208c may also extend in the same direction as the fin structures 208b, and may be formed in the same set of one or more semiconductor processing operations as the fin structures 208a and the fin structures 208b. Thus, the orientation of the pattern 902 may be rotated approximately 90 degrees relative to the pattern 302 because of the pattern 902 being formed in the fin structures 208c, as opposed to the pattern 302 being formed in the dummy gate structures 212b (or gate structures 608b).

Including both the pattern 302 (e.g., the polysilicon-gate-based alignment mark pattern or dummy-gate-based alignment mark pattern) and the pattern 902 (e.g., the fin based alignment mark pattern or OD based alignment mark pattern) enables the pattern 302 and the pattern 902 for alignment of the substrate 202 to be used for different stages of manufacturing of the semiconductor devices 900 on the substrate 202. For example, the pattern 902 may be formed as a part of (or after) the fin formation process described in connection with FIGS. 4A-4D, and may be used for alignment of the substrate 202 for the semiconductor processes performed for forming the dummy gate structures 212a and 212b, as described in connection with FIGS. 5A-5F. After the formation of the dummy gate structures 212a and 212b, the pattern 302 may be used for alignment of the substrate 202 in subsequent semiconductor processes.

As indicated above, FIGS. 9A-9C are provided as an example. Other examples may differ from what is described with regard to FIGS. 9A-9C.

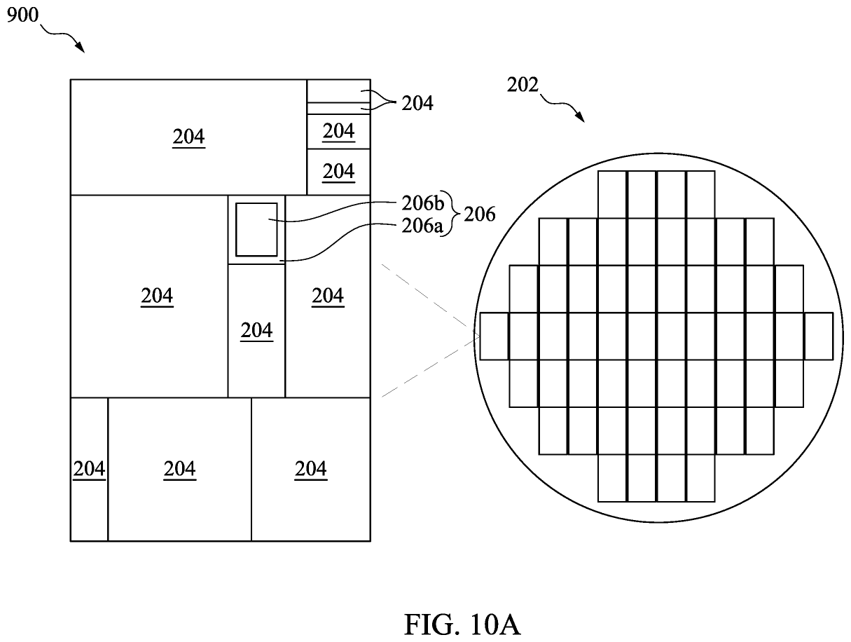

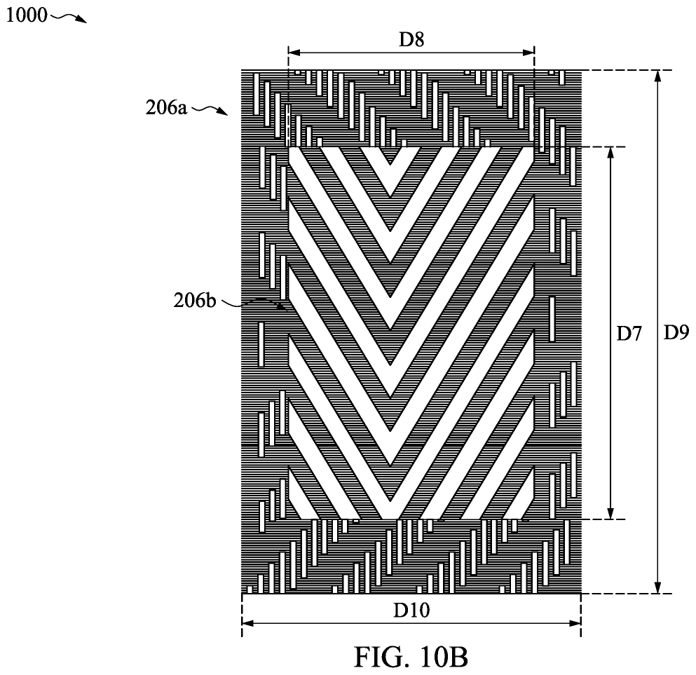

FIGS. 10A and 10B are diagrams of example regions of a semiconductor device 1000 described herein. The semiconductor device 1000 may include a semiconductor die, a semiconductor chiplet, and/or another type of semiconductor device that is manufactured on a substrate 202.

As shown in FIG. 10A, the semiconductor device 1000 may be similar to the semiconductor device 900 and may include one or more active device regions 204 and one or more alignment mark regions 206 (e.g., the alignment mark region 206a, the alignment mark region 206b). The layout, shape, quantity, and/or arrangement of active device regions 204 and alignment mark regions 206 illustrated in FIG. 10A are examples, and other layouts, shapes, quantities, and/or arrangements are within the scope of the present disclosure.

As further shown in the semiconductor device 1000 in FIGS. 10A and 10B, the alignment mark region 206a may be included around the perimeter of the alignment mark region 206b in the top-down layout of the semiconductor device 1000. The alignment mark region 206b may include a dimension D7 (corresponding to a width of the alignment mark region 206b) and a dimension D8 (corresponding to a length of the alignment mark region 206b). The alignment mark region 206a may include a dimension D9 (corresponding to a width of the alignment mark region 206a) and a dimension D10 (corresponding to a length of the alignment mark region 206b). In some implementations, the dimension D7 is included in a range of approximately 100 microns to approximately 300 microns. However, other values for the range are within the scope of the present disclosure. In some implementations, the dimension D8 is included in a range of approximately 100 microns to approximately 300 microns. However, other values for the range are within the scope of the present disclosure. In some implementations, a ratio of the dimension D7 to D9 (D7:D9) is included in a range of approximately 1:1.1 to approximately 1:1.5. However, other values for the range are within the scope of the present disclosure. In some implementations, a ratio of the dimension D8 to D10 (D8:D10) is included in a range of approximately 1:1.1 to approximately 1:1.5. However, other values for the range are within the scope of the present disclosure.

Including both the alignment mark region 206a (e.g., the polysilicon-gate-based alignment mark or dummy-gate-based alignment mark) and the alignment mark region 206b (e.g., the fin based alignment mark or OD based alignment mark) enables the alignment mark region 206a and the alignment mark region 206b to be used for alignment of the substrate 202 for different stages of manufacturing of the semiconductor devices 1000 on the substrate 202. For example, the alignment mark region 206b may be formed as a part of (or after) the fin formation process described in connection with FIGS. 4A-4D, and may be used for alignment of the substrate 202 for the semiconductor processes performed for forming the dummy gate structures 212a and 212b, as described in connection with FIGS. 5A-5F. After the formation of the dummy gate structures 212a and 212b, the alignment mark region 206a may be used for alignment of the substrate 202 in subsequent semiconductor processes.

As indicated above, FIGS. 10A and 10B are provided as an example. Other examples may differ from what is described with regard to FIGS. 10A and 10B.

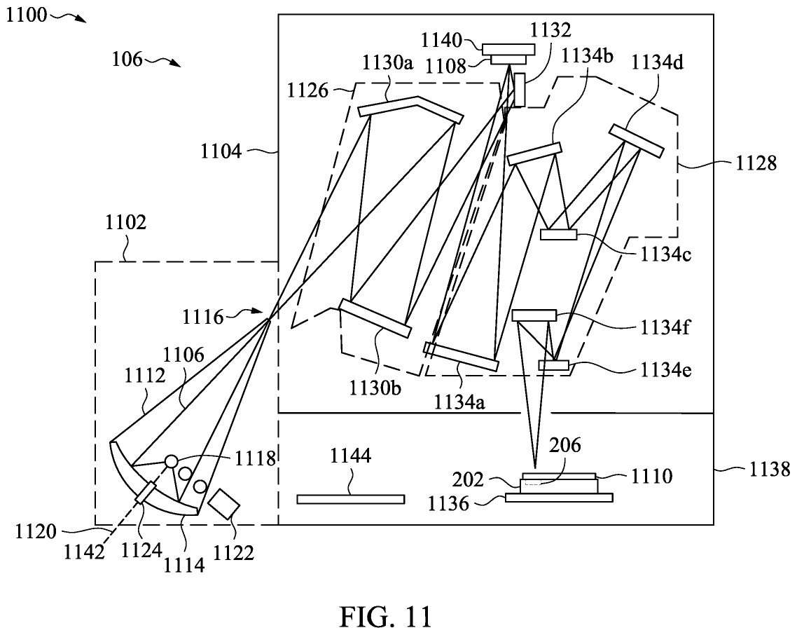

FIG. 11 is a diagram of an example lithography system 1100 described herein. The lithography system 1100 includes an EUV lithography system or another type of lithography system that is configured to transfer a pattern to a substrate 202 using mirror-based optics. The lithography system 1100 includes an example of an exposure tool 106. The lithography system 1100 may be configured for use in a semiconductor processing environment such as the example environment 100 described in connection with FIG. 1.

As shown in FIG. 11, the lithography system 1100 includes the radiation source 1102 and an exposure tool 1104. The radiation source 1102 (e.g., an EUV radiation source or another type of radiation source) is configured to generate radiation 1106 such as EUV radiation and/or another type of electromagnetic radiation (e.g., light). The exposure tool 1104 (e.g., an EUV scanner or another type of exposure tool) is configured to focus the radiation 1106 onto a reflective reticle 1108 (or a photomask) such that a pattern is transferred from the reticle 1108 onto a photoresist layer 1110 the substrate 202 using the radiation 1106.

The radiation source 1102 includes a vessel 1112 and a collector 1114 in the vessel 1112. The collector 1114, includes a curved mirror that is configured to collect the radiation 1106 generated by the radiation source 1102 and to focus the radiation 1106 toward an intermediate focus 1116. The radiation 1106 is produced from a plasma that is generated from droplets 1118 (e.g., tin (Sn) droplets or another type of droplets) being exposed to a laser beam 1120. The droplets 1118 are provided across the front of the collector 1114 by a droplet generator (DG) head 1122. The DG head 1122 is pressurized to provide a fine and controlled output of the droplets 1118.

A laser source, such as a pulse carbon dioxide (CO₂) laser, generates the laser beam 1120. The laser beam 1120 is provided (e.g., by a beam delivery system to a focus lens) such that the laser beam 1120 is focused through a window 1124 of the collector 1114. The laser beam 1120 is focused onto the droplets 1118 which generates the plasma. The plasma produces a plasma emission, some of which is the radiation 1106. The laser beam 1120 is pulsed at a timing that is synchronized with the flow of the droplets 1118 from the DG head 1122.

The exposure tool 1104 includes an illuminator 1126 and a projection optics box (POB) 1128. The illuminator 1126 includes a plurality of reflective mirrors that are configured to focus and/or direct the radiation 1106 onto the reticle 1108 so as to illuminate the pattern on the reticle 1108. The plurality of mirrors include, for example, a mirror 1130a and a mirror 1130b. The mirror 1130a includes a field facet mirror (FFM) or another type of mirror that includes a plurality of field facets. The mirror 1130b includes a pupil facet mirror (PFM) or another type of mirror that also includes a plurality of pupil facets. The facets of the mirrors 1130a and 1130b are arranged to focus, polarize, and/or otherwise tune the radiation 1106 from the radiation source 1102 to increase the uniformity of the radiation 1106 and/or to increase particular types of radiation components (e.g., transverse electric (TE) polarized radiation, transverse magnetic (TM) polarized radiation). Another mirror 1132 (e.g., a relay mirror) is included to direct radiation 1106 from the illuminator 1126 onto the reticle 1108.

The projection optics box 1128 includes a plurality of mirrors that are configured to project the radiation 1106 onto the photoresist layer 1110 on the substrate 202 after the radiation 1106 is modified based on the pattern of the reticle 1108. The plurality of reflective mirrors include, for example, mirrors 1134a-1134f. In some implementations, the mirrors 1134a-1134f are configured to focus or reduce the radiation 1106 into an exposure field, which may include one or more die areas on the substrate 202.

The exposure tool 1104 includes a wafer stage 1136 (e.g., a substrate stage) configured to support the substrate 202. Moreover, the wafer stage 1136 is configured to move (or step) the substrate 202 through a plurality of exposure fields as the radiation 1106 transfers the pattern from the reticle 1108 onto the photoresist layer 1110 on the substrate 202. The wafer stage 1136 is included in a bottom module 1138 of the exposure tool 1104. The bottom module 1138 includes a removable subsystem of the exposure tool 1104. The bottom module 1138 may slide out of the exposure tool 104 and/or otherwise may be removed from the exposure tool 1104 to enable cleaning and inspection of the wafer stage 1136 and/or the components of the wafer stage 1136. The bottom module 1138 isolates the wafer stage 1136 from other areas in the exposure tool 1104 to reduce and/or minimize contamination of the substrate 202. Moreover, the bottom module 1138 may provide physical isolation for the wafer stage 1136 by reducing the transfer of vibrations (e.g., vibrations in the semiconductor processing environment in which the lithography system 1100 is located, vibrations in the lithography system 1100 during operation of the lithography system 1100) to the wafer stage 1136 and, therefore, the substrate 202. This reduces movement and/or disturbance of the substrate 202, which reduces the likelihood that the vibrations may cause a pattern misalignment.

The exposure tool 1104 also includes a reticle stage 1140 that configured to support and/or secure the reticle 1108. Moreover, the reticle stage 1140 is configured to move or slide the reticle through the radiation 1106 such that the reticle 1108 is scanned by the radiation 1106. In this way, a pattern that is larger than the field or beam of the radiation 1106 may be transferred to the photoresist layer 1110 on the substrate 202.

The lithography system 1100 includes a laser source 1142. The laser source 1142 is configured to generate the laser beam 1120. The laser source 1142 may include a CO₂-based laser source or another type of laser source. Due to the wavelength of the laser beams generated by a CO₂-based laser source in an infrared (IR) region, the laser beams may be highly absorbed by tin, which enables the CO₂-based laser source to achieve high power and energy for pumping tin-based plasma. In some implementations, the laser beam 1120 includes a plurality of types of laser beams that the laser source 1142 generates using a multi-pulse technique (or a multi-stage pumping technique), in which the laser source 1142 generates a pre-pulse laser beam and main-pulse laser beam to achieve greater heating efficiency of tin (Sn)-based plasma to increase conversion efficiency.

In an example exposure operation (e.g., an EUV exposure operation), the DG head 1122 provides the stream of the droplets 1118 across the front of the collector 1114. The laser beam 1120 contacts the droplets 1118, which causes a plasma to be generated. The laser source 1142 generates and provides a pre-pulse laser beam toward a target material droplet in the stream of the droplets 1118, and the pre-pulse laser beam is absorbed by the target material droplet. This transforms the target material droplet into disc shape or a mist. Subsequently, the laser source 1142 provides a main-pulse laser beam with large intensity and energy toward the disc-shaped target material or target material mist. Here, the atoms of the target material are neutralized, and ions are generated through thermal flux and shock wave. The main-pulse laser beam pumps ions to a higher charge state, which causes the ions to radiate the radiation 1106 (e.g., EUV light).

The radiation 1106 is collected by the collector 1114 and directed out of the vessel 1112 and into the exposure tool 1104 toward the mirror 1130a of the illuminator 1126. The mirror 1130a reflects the radiation 1106 onto the mirror 1130b, which reflects the radiation 1106 onto the mirror 1132 toward the reticle 1108. The radiation 1106 is modified by the pattern in the reticle 1108. In other words, the radiation 1106 reflects off of the reticle 1108 based on the pattern of the reticle 1108. The reflective reticle 1108 directs the radiation 1106 toward the mirror 1134a in the projection optics box 1128, which reflects the radiation 1106 onto the mirror 1134b. The radiation 1106 continues to be reflected and reduced in the projection optics box 1128 by the mirrors 1134c-1134f. The mirror 1134f reflects the radiation 1106 onto the photoresist layer 1110 on the substrate 202 such that the pattern of the reticle 1108 is transferred to the photoresist layer 1110 on the substrate 202. The above-described exposure operation is an example, and the lithography system 1100 may operate according to other EUV techniques and radiation paths that include a greater quantity of mirrors, a lesser quantity of mirrors, and/or a different configuration of mirrors.

As further shown in FIG. 11, a pre-alignment unit 1144 may be included in the bottom module 1138. The pre-alignment unit 1144 (also referred to as a temperature stabilizing unit (TSU)) may be configured to perform coarse alignment of the substrate 202 prior to an exposure operation. The pre-alignment unit 1144 may also be used for performing measurements and/or determining yellow light OVL compensation values for the exposure operation. After coarse alignment, the alignment mark region 206 (e.g., the polysilicon-gate-based alignment mark or the dummy-gate-based alignment mark) on the substrate 202 may be used to perform fine wafer alignment of the substrate 202 for the exposure operation. In some implementations, the yellow light OVL compensation values may be used during the fine wafer alignment of the substrate 202.

As indicated above, FIG. 11 is provided as an example. Other examples may differ from what is described with regard to FIG. 11.

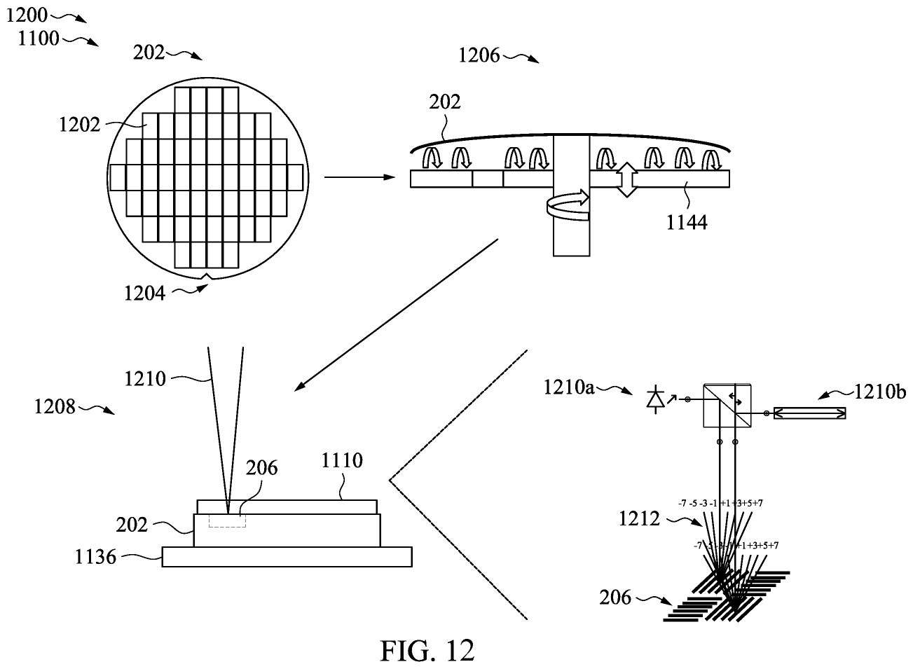

FIG. 12 is a diagram of an example implementation 1200 of performing alignment of a substrate described herein. As shown in FIG. 12, a substrate 202 may include a plurality of semiconductor devices 1202 that are in the process of being manufactured on the substrate 202. The semiconductor devices 1202 may include semiconductor devices 200, semiconductor devices 800, semiconductor devices 900, semiconductor devices 1000, and/or other semiconductor devices that include a polysilicon-gate-based alignment mark or a dummy-gate-based alignment mark described herein. The substrate 202 may also include a notch 1204 at the perimeter of the substrate 202.

A coarse wafer alignment (COWA) operation 1206 may be performed in which the substrate 202 is placed on the pre-alignment unit 1144 of the lithography system 1100 and rotated in one or more directions to align the notch 1204 of the substrate 202 with a reference location on the pre-alignment unit 1144. At least two sites may be selected to determine the reference origin of the coordinate system (e.g., Cartesian coordinates, polar coordinates) for the alignment of the notch 1204 and the reference location.

After the COWA operation 1206, a fine wafer alignment (FIWA) operation 1208 may be performed in which a plurality of laser beams 1210 are used to scan the alignment mark region 206 on the substrate 202. A green laser beam 1210a and a red laser beam 1210b may be directed onto the alignment mark region 206, where the pattern 302 in the alignment mark region scatters the green laser beam 1210a and the red laser beam 1210b. The reflected and diffracted orders of reflected light 1212 from the green laser beam 1210a and the red laser beam 1210b may be measured to determine alignment of the substrate 202 in the FIWA operation 1208 and to fine-tune the orientation of the substrate on the wafer stage 1136.

As indicated above, FIG. 12 is provided as an example. Other examples may differ from what is described with regard to FIG. 12.

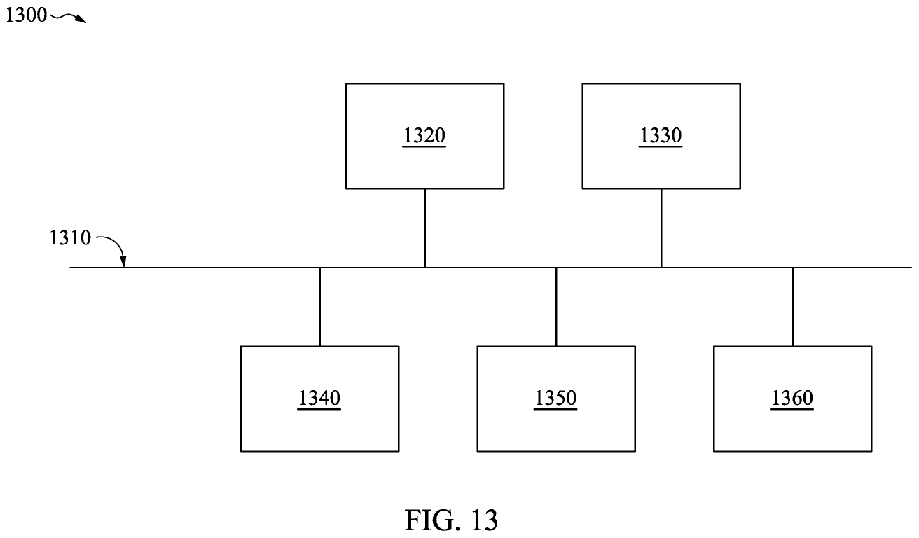

FIG. 13 is a diagram of example components of a device 1300 associated with semiconductor device including an alignment mark. In some implementations, one or more of the semiconductor processing tools 102-112, the wafer/die transport tool 114, and/or the lithography system 1100 may include one or more devices 1300 and/or one or more components of the device 1300. As shown in FIG. 13, the device 1300 may include a bus 1310, a processor 1320, a memory 1330, an input component 1340, an output component 1350, and/or a communication component 1360.

The bus 1310 may include one or more components that enable wired and/or wireless communication among the components of the device 1300. The bus 1310 may couple together two or more components of FIG. 13, such as via operative coupling, communicative coupling, electronic coupling, and/or electric coupling. For example, the bus 1310 may include an electrical connection (e.g., a wire, a trace, and/or a lead) and/or a wireless bus. The processor 1320 may include a central processing unit, a graphics processing unit, a microprocessor, a controller, a microcontroller, a digital signal processor, a field-programmable gate array, an application-specific integrated circuit, and/or another type of processing component. The processor 1320 may be implemented in hardware, firmware, or a combination of hardware and software. In some implementations, the processor 1320 may include one or more processors capable of being programmed to perform one or more operations or processes described elsewhere herein.

The memory 1330 may include volatile and/or nonvolatile memory. For example, the memory 1330 may include random access memory (RAM), read only memory (ROM), a hard disk drive, and/or another type of memory (e.g., a flash memory, a magnetic memory, and/or an optical memory). The memory 1330 may include internal memory (e.g., RAM, ROM, or a hard disk drive) and/or removable memory (e.g., removable via a universal serial bus connection). The memory 1330 may be a non-transitory computer-readable medium. The memory 1330 may store information, one or more instructions, and/or software (e.g., one or more software applications) related to the operation of the device 1300. In some implementations, the memory 1330 may include one or more memories that are coupled (e.g., communicatively coupled) to one or more processors (e.g., processor 1320), such as via the bus 1310. Communicative coupling between a processor 1320 and a memory 1330 may enable the processor 1320 to read and/or process information stored in the memory 1330 and/or to store information in the memory 1330.

The input component 1340 may enable the device 1300 to receive input, such as user input and/or sensed input. For example, the input component 1340 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1350 may enable the device 1300 to provide output, such as via a display, a speaker, and/or a light-emitting diode. The communication component 1360 may enable the device 1300 to communicate with other devices via a wired connection and/or a wireless connection. For example, the communication component 1360 may include a receiver, a transmitter, a transceiver, a modem, a network interface card, and/or an antenna.

The device 1300 may perform one or more operations or processes described herein. For example, a non-transitory computer-readable medium (e.g., memory 1330) may store a set of instructions (e.g., one or more instructions or code) for execution by the processor 1320. The processor 1320 may execute the set of instructions to perform one or more operations or processes described herein. In some implementations, execution of the set of instructions, by one or more processors 1320, causes the one or more processors 1320 and/or the device 1300 to perform one or more operations or processes described herein. In some implementations, hardwired circuitry may be used instead of or in combination with the instructions to perform one or more operations or processes described herein. Additionally, or alternatively, the processor 1320 may be configured to perform one or more operations or processes described herein. Thus, implementations described herein are not limited to any specific combination of hardware circuitry and software.

The number and arrangement of components shown in FIG. 13 are provided as an example. The device 1300 may include additional components, fewer components, different components, or differently arranged components than those shown in FIG. 13. Additionally, or alternatively, a set of components (e.g., one or more components) of the device 1300 may perform one or more functions described as being performed by another set of components of the device 1300.

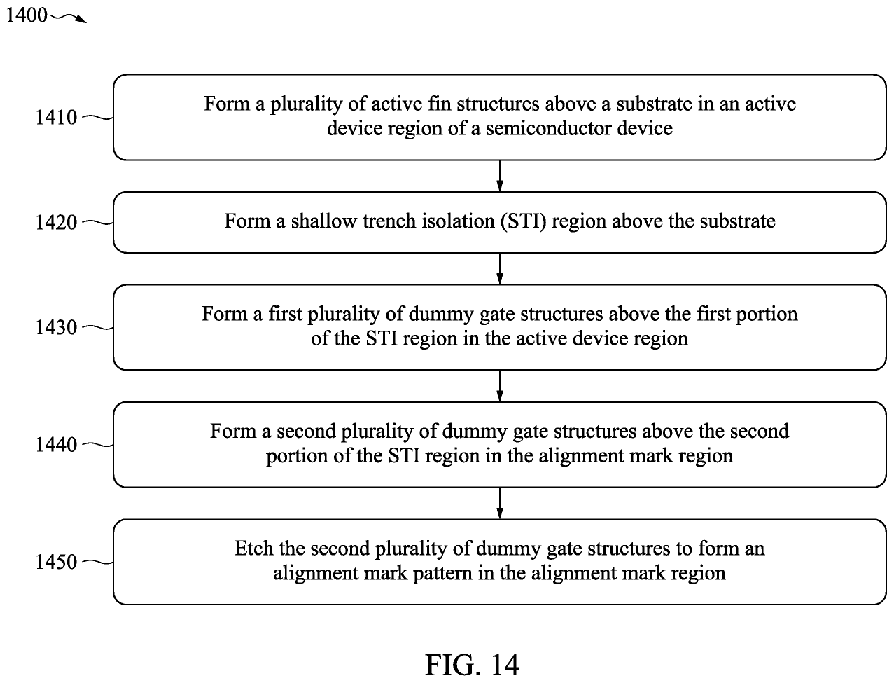

FIG. 14 is a flowchart of an example process 1400 associated with forming a semiconductor device including an alignment mark described herein. In some implementations, one or more process blocks of FIG. 14 are performed using one or more semiconductor processing tools (e.g., one or more of the semiconductor processing tools 102-112). Additionally, or alternatively, one or more process blocks of FIG. 14 may be performed using one or more components of device 1300, such as processor 1320, memory 1330, input component 1340, output component 1350, and/or communication component 1360.

As shown in FIG. 14, process 1400 may include forming a plurality of active fin structures above a substrate in an active device region of a semiconductor device (block 1410). For example, one or more of the semiconductor processing tools 102-112 may be used to form a plurality of active fin structures (e.g., fin structures 208a) above a substrate 202 in an active device region 204 of a semiconductor device (e.g., a semiconductor device 200, 800, 900, and/or 1000), as described herein.

As further shown in FIG. 14, process 1400 may include forming an STI region above the substrate (block 1420). For example, one or more of the semiconductor processing tools 102-112 may be used to form an STI region (e.g., an STI layer 210) above the substrate, as described herein. In some implementations, a first portion of the STI region (e.g., STI regions 210a) is formed between the plurality of active fin structures in the active device region. In some implementations, a second portion of the STI region (e.g., STI regions 210b) is formed above the substrate in an alignment mark region (e.g., an alignment mark region 206, an alignment mark region 206a) of the semiconductor device.

As further shown in FIG. 14, process 1400 may include forming a first plurality of dummy gate structures above the first portion of the STI region in the active device region (block 1430). For example, one or more of the semiconductor processing tools 102-112 may be used to form a first plurality of dummy gate structures 212a above the first portion of the STI region in the active device region, as described herein. In some implementations, the first plurality of dummy gate structures wrap around the plurality of active fin structures on at least three sides of the plurality of active fin structures.

As further shown in FIG. 14, process 1400 may include forming a second plurality of dummy gate structures (212b) above the second portion of the STI region in the alignment mark region (block 1440). For example, one or more of the semiconductor processing tools 102-112 may be used to form a second plurality of dummy gate structures 212b above the second portion of the STI region in the alignment mark region, as described herein.

As further shown in FIG. 14, process 1400 may include etching the second plurality of dummy gate structures to form an alignment mark pattern in the alignment mark region (block 1450). For example, one or more of the semiconductor processing tools 102-112 may be used to etch the second plurality of dummy gate structures to form an alignment mark pattern (e.g., a pattern 302) in the alignment mark region, as described herein.

Process 1400 may include additional implementations, such as any single implementation or any combination of implementations described below and/or in connection with one or more other processes described elsewhere herein.

In a first implementation, process 1400 includes forming a plurality of non-active fin structures (e.g., fin structures 208b) above the substrate in the alignment mark region, where the second portion of the STI region is formed between the plurality of non-active fin structures, and where forming the second plurality of dummy gate structures includes forming the second plurality of dummy gate structures such that the second plurality of dummy gate structures wrap around the plurality of non-active fin structures on at least three sides of the plurality of non-active fin structures.

In a second implementation, alone or in combination with the first implementation, process 1400 includes forming a plurality of source/drain regions 514 on opposing sides of the first plurality of dummy gate structures while the second plurality of dummy gate structures are covered by a masking layer 510.

In a third implementation, alone or in combination with one or more of the first and second implementations, process 1400 includes forming a CESL (e.g., a CESL 602a, a CESL 602b) on the first plurality of dummy gate structures and on the second plurality of dummy gate structures, forming an ILD layer (e.g., an ILD layer 604a, an ILD layer 604b) on the CESL, performing a plurality of planarization operations to remove the CESL and the ILD layer from tops of the first plurality of dummy gate structures and tops of the second plurality of dummy gate structures to expose the first plurality of dummy gate structures and the second plurality of dummy gate structures through the CESL and through the ILD layer, removing the first plurality of dummy gate structures and the second plurality of dummy gate structures after the plurality of planarization operations, forming a plurality of active metal gate structures (e.g., gate structures 608a) in first recesses (e.g., recesses 606a) formed by removal of the first plurality of dummy gate structures, and forming a plurality of non-active metal gate structures (e.g., gate structures 608b) in second recesses (e.g., recesses 606a) formed by removal of the second plurality of dummy gate structures.

In a fourth implementation, alone or in combination with one or more of the first through third implementations, the plurality of non-active metal gate structures each include a conductive structure (e.g., a metal electrode 702), a WFM layer (e.g., a WFM layer 706), an adhesion layer (e.g., a glue layer 704) between the conductive structure and the WFM layer, a high-k dielectric layer (e.g., a high-k dielectric layer 712) under the WFM layer, and an interface layer (e.g., an interfacial layer 714) under the high-k dielectric layer.

In a fifth implementation, alone or in combination with one or more of the first through fourth implementations, the plurality of non-active metal gate structures each include a conductive structure (e.g., a metal electrode 702), a plurality of WFM layers (e.g., WFM layers 706, 720, 724, and/or 728), an adhesion layer (e.g., a glue layer 704) between the conductive structure and the plurality of WFM layers, a high-k dielectric layer (e.g., a high-k dielectric layer 712) under the plurality of WFM layer, and an interface layer (e.g., an interfacial layer 714) under the high-k dielectric layer.

In a sixth implementation, alone or in combination with one or more of the first through fifth implementations, etching the second plurality of dummy gate structures to form the alignment mark pattern in the alignment mark region includes etching the second plurality of dummy gate structures such that the alignment mark pattern includes a plurality of approximately chevron-shaped gaps (e.g., gaps 308) between rows (e.g., rows 304, 306) of the second plurality of dummy gate structures.

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

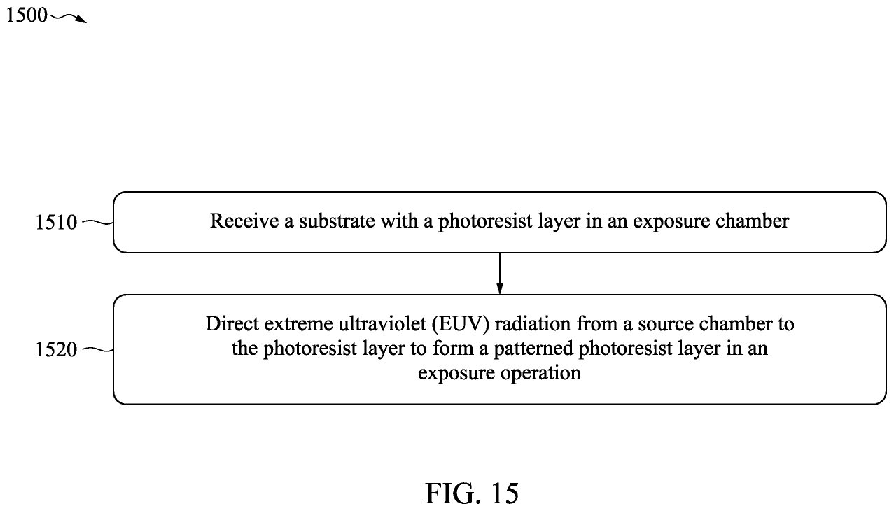

FIG. 15 is a flowchart of an example process 1500 associated with alignment of a semiconductor device using an alignment mark described herein. In some implementations, one or more process blocks of FIG. 15 are performed using a lithography system (e.g., lithography system 1100). Additionally, or alternatively, one or more process blocks of FIG. 15 may be performed by one or more components of device 1300, such as processor 1320, memory 1330, input component 1340, output component 1350, and/or communication component 1360.

As shown in FIG. 15, process 1500 may include receiving a substrate with a photoresist layer in an exposure tool (block 1510). For example, the lithography system 1100 may be used to receive a substrate 202 with a photoresist layer 1110 in an exposure tool 1104, as described herein.

As further shown in FIG. 15, process 1500 may include directing EUV radiation from a radiation source to the photoresist layer to form a patterned photoresist layer in an exposure operation (block 1520). For example, the lithography system 1100 may be used to direct EUV radiation from a radiation source 1102 to the photoresist layer 1110 to form a patterned photoresist layer in an exposure operation, as described herein. In some implementations, a polysilicon-gate-based alignment mark pattern (e.g., a pattern 302) in a polysilicon-gate-based alignment mark region (e.g., an alignment mark region 206, an alignment mark region 206a) is used to align the substrate 202 for the exposure operation.

Process 1500 may include additional implementations, such as any single implementation or any combination of implementations described below and/or in connection with one or more other processes described elsewhere herein.

In a first implementation, the exposure operation includes a second exposure operation, and process 1500 includes directing EUV radiation from the radiation source 1102 to another photoresist layer 1110 to form another patterned photoresist layer in a first exposure operation that is performed prior to the second exposure operation, where a fin based alignment mark pattern (e.g., a pattern 902) in a fin based alignment mark region (e.g., an alignment mark region 206b) is used to align the substrate 202 for the first exposure operation.

In a second implementation, alone or in combination with the first implementation, the fin based alignment mark region and the polysilicon-gate based alignment mark region are located in different regions of the substrate 202.

In a third implementation, alone or in combination with one or more of the first and second implementations, the polysilicon-gate based alignment mark region is located around a perimeter of the fin based alignment mark region.

Although FIG. 15 shows example blocks of process 1500, in some implementations, process 1500 includes additional blocks, fewer blocks, different blocks, or differently arranged blocks than those depicted in FIG. 15. Additionally, or alternatively, two or more of the blocks of process 1500 may be performed in parallel.

In this way, a gate based alignment pattern may be included in an alignment mark region in a semiconductor device that is manufactured on the substrate. The alignment mark region may include a plurality of gate structures (e.g., dummy gate structures, polysilicon gate structures, metal gate structures) that are etched to form a gate based alignment pattern. The use of the gate based alignment pattern may reduce the likelihood of and/or may prevent the gate based alignment pattern from becoming obscured or covered by residual material byproducts from one or more semiconductor processing operations that are performed to form various layers and/or structures of the semiconductor device. For example, the gate based alignment pattern may enable a gate spacing parameter or design rule for the semiconductor device to be satisfied in the alignment mark region. This may reduce the likelihood of dishing in the dielectric layer above the gate structures in the alignment mark region. The dishing may be prevented (or the magnitude of dishing may be minimized) in that the close spacing of gate structures in the alignment mark region may prevent or reduce the magnitude of polishing pad deformation when the dielectric layer is planarized (e.g., as part of the replacement gate process). The reduced magnitude or prevention of the dishing in the dielectric layer may reduce the likelihood of and/or prevent residual metal material and/or other material, that is deposited as part of the replacement gate process to form the metal gate structures of the semiconductor device, from being retained above the dielectric layer in the alignment mark region. Accordingly, the gate based alignment pattern of the alignment mark region may reduce the likelihood of and/or prevent residual metal material and/or other material from obscuring or blocking the pattern in the alignment mark region.

As described in greater detail above, some implementations described herein provide a semiconductor device. The semiconductor device includes one or more device regions including a plurality of active transistor structures. The semiconductor device includes an alignment mark, adjacent to at least a subset of the one or more device regions, including a plurality of non-active gate structures arranged in a pattern.

As described in greater detail above, some implementations described herein provide a method. The method includes forming a plurality of active fin structures above a substrate in an active device region of a semiconductor device. The method includes forming a STI region above the substrate, where a first portion of the STI region is formed between the plurality of active fin structures in the active device region, and where a second portion of the STI region is formed above the substrate in an alignment mark region of the semiconductor device. The method includes forming a first plurality of dummy gate structures above the first portion of the STI region in the active device region, where the first plurality of dummy gate structures wrap around the plurality of active fin structures on at least three sides of the plurality of active fin structures. The method includes forming a second plurality of dummy gate structures above the second portion of the STI region in the alignment mark region. The method includes etching the second plurality of dummy gate structures to form an alignment mark pattern in the alignment mark region.

As described in greater detail above, some implementations described herein provide a method. The method includes receiving a substrate with a photoresist layer in an exposure tool. The method includes directing EUV radiation from a radiation source to the photoresist layer to form a patterned photoresist layer in an exposure operation, where a polysilicon-gate-based alignment mark pattern in a polysilicon-gate-based alignment mark region is used to align the substrate for the exposure operation.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
one or more device regions including a plurality of active transistor structures; and
an alignment mark, adjacent to at least a subset of the one or more device regions, including a plurality of non-active gate structures arranged in a pattern.

2. The semiconductor device of claim 1, wherein the pattern comprises:
a plurality of rows of the plurality of non-active gate structures,
wherein the plurality of rows are spaced apart by gaps between the plurality of rows.

3. The semiconductor device of claim 1, wherein the alignment mark further comprises:
a plurality of non-active fin structures,
wherein the plurality of non-active gate structures wrap around the plurality of non-active fin structures on at least three sides of the plurality of non-active fin structures.

4. The semiconductor device of claim 3, wherein the plurality of non-active fin structures extend in a first direction in the semiconductor device; and
wherein the plurality of non-active gate structures extend in a second direction, in the semiconductor device, that is approximately perpendicular to the first direction.

5. The semiconductor device of claim 3, wherein the pattern comprises:
a plurality of rows of the plurality of non-active gate structures,
wherein the plurality of rows extend in a non-perpendicular direction relative to a direction in which the plurality of non-active fin structures extend.

6. The semiconductor device of claim 1, wherein the plurality of active transistor structures include a plurality of active gate structures; and
wherein a spacing between two or more of the plurality of non-active gate structures, and a spacing between two or more of the plurality of active gate structures, are approximately a same spacing.

7. The semiconductor device of claim 1, wherein the alignment mark further comprises:
a shallow trench isolation (STI) region over a substrate of the semiconductor device, wherein the plurality of non-active gate structures are included on the STI region.

8. The semiconductor device of claim 1, wherein the alignment mark comprises a first alignment mark;
wherein the semiconductor device further comprises a second alignment mark including a plurality of non-active fin structures arranged in another pattern; and
wherein the second alignment mark is adjacent to at least another subset of the one or more device regions.

9. The semiconductor device of claim 1, wherein the pattern comprises a first pattern;
wherein the alignment mark further comprises a plurality of non-active fin structures arranged in a second pattern; and
wherein the first pattern is located around a perimeter of the second pattern.

10. A method, comprising:
forming a plurality of active fin structures above a substrate in an active device region of a semiconductor device;
forming a shallow trench isolation (STI) region above the substrate,
wherein a first portion of the STI region is formed between the plurality of active fin structures in the active device region, and
wherein a second portion of the STI region is formed above the substrate in an alignment mark region of the semiconductor device;
forming a first plurality of dummy gate structures above the first portion of the STI region in the active device region,
wherein the first plurality of dummy gate structures wrap around the plurality of active fin structures on at least three sides of the plurality of active fin structures;
forming a second plurality of dummy gate structures above the second portion of the STI region in the alignment mark region; and
etching the second plurality of dummy gate structures to form an alignment mark pattern in the alignment mark region.

11. The method of claim 10, further comprising:
forming a plurality of non-active fin structures above the substrate in the alignment mark region,
wherein the second portion of the STI region is formed between the plurality of non-active fin structures, and
wherein forming the second plurality of dummy gate structures comprises:
forming the second plurality of dummy gate structures such that the second plurality of dummy gate structures wrap around the plurality of non-active fin structures on at least three sides of the plurality of non-active fin structures.

12. The method of claim 10, further comprising:
forming a plurality of source/drain regions on opposing sides of the first plurality of dummy gate structures while the second plurality of dummy gate structures are covered by a masking layer.

13. The method of claim 10, further comprising:
forming a contact etch stop layer (CESL) on the first plurality of dummy gate structures and on the second plurality of dummy gate structures;
forming an interlayer dielectric (ILD) layer on the CESL;
performing a plurality of planarization operations to remove the CESL and the ILD layer from tops of the first plurality of dummy gate structures and tops of the second plurality of dummy gate structures to expose the first plurality of dummy gate structures and the second plurality of dummy gate structures through the CESL and through the ILD layer;
removing the first plurality of dummy gate structures and the second plurality of dummy gate structures after the plurality of planarization operations;
forming a plurality of active metal gate structures in first recesses formed by removal of the first plurality of dummy gate structures; and
forming a plurality of non-active metal gate structures in second recesses formed by removal of the second plurality of dummy gate structures.

14. The method of claim 13, wherein the plurality of non-active metal gate structures each comprise:
a conductive structure;
a work function metal layer;
an adhesion layer between the conductive structure and the work function metal layer;
a high dielectric constant (high-k) dielectric layer under the work function metal layer; and
an interface layer between under the high-k dielectric layer.

15. The method of claim 13, wherein the plurality of non-active metal gate structures each comprise:
a conductive structure;
a plurality of work function metal layers;
an adhesion layer between the conductive structure and the plurality of work function metal layers;
a high dielectric constant (high-k) dielectric layer under the plurality of work function metal layers; and
an interface layer under the high-k dielectric layer.

16. The method of claim 10, wherein etching the second plurality of dummy gate structures to form the alignment mark pattern in the alignment mark region comprises:
etching the second plurality of dummy gate structures such that the alignment mark pattern includes a plurality of approximately chevron-shaped gaps between rows of the second plurality of dummy gate structures.

17. A method, comprising:
receiving a substrate with a photoresist layer in an exposure tool; and
directing extreme ultraviolet (EUV) radiation from a radiation source to the photoresist layer to form a patterned photoresist layer in an exposure operation,
wherein a polysilicon-gate-based alignment mark pattern in a polysilicon-gate-based alignment mark region is used to align the substrate for the exposure operation.

18. The method of claim 17, wherein the exposure operation comprises a second exposure operation; and
wherein the method further comprises:
directing EUV radiation from the radiation source to another photoresist layer to form another patterned photoresist layer in a first exposure operation that is performed prior to the second exposure operation,
wherein a fin based alignment mark pattern in a fin based alignment mark region is used to align the substrate for the first exposure operation.

19. The method of claim 18, wherein the fin based alignment mark region and the polysilicon-gate based alignment mark region are located in different regions of the substrate.

20. The method of claim 18, wherein the polysilicon-gate based alignment mark region is located around a perimeter of the fin based alignment mark region.
